(19) United States
(12) Patent Application Publication
(10) Pub. No.: US 2022/0254918 A1
(43) Pub. Date: Aug. 11, 2022

(54) METHODS AND SYSTEMS FOR FABRICATION OF VERTICAL FIN-BASED JFETS

(71) Applicant: NexGen Power Systems, Inc., Santa Clara, CA (US)

(72) Inventors: Clifford Drowley, Santa Clara, CA (US); Hao Cui, Santa Clara, CA (US); Andrew P. Edwards, Santa Clara, CA (US); Subhash Srinivas Pidaparthi, Santa Clara, CA (US)

(73) Assignee: NexGen Power Systems, Inc., Santa Clara, CA (US)

(21) Appl. No.: 17/667,432

(22) Filed: Feb. 8, 2022

Related U.S. Application Data
(60) Provisional application No. 63/148,024, filed on Feb. 10, 2021.

(51) Int. Cl. H01L 29/78; H01L 29/66; H01L 29/417; H01L 29/45; H01L 29/423

(52) U.S. Cl. CPC H01L 29/785; H01L 29/66803; H01L 29/42356; H01L 29/452; H01L 29/41791

(57) ABSTRACT

A vertical FET device includes a semiconductor structure comprising a semiconductor substrate, a first semiconductor layer coupled to the semiconductor substrate, and a second semiconductor layer coupled to the first semiconductor layer. The vertical FET device also includes a plurality of fins. Adjacent fins of the plurality of fins are separated by a trench extending into the second semiconductor layer and each of the plurality of fins includes a channel region disposed in the second semiconductor layer. The vertical FET also includes a gate region extending into a sidewall portion of the channel region of each of the plurality of fins, a source metal structure coupled to the second semiconductor layer, a gate metal structure coupled to the gate region, and a drain contact coupled to the semiconductor substrate.

### CROSS-REFERENCES TO RELATED APPLICATIONS

This application claims the benefit of and priority to U.S. Provisional Patent Application No. 63/148,024, filed on Feb. 10, 2021, the disclosure of which is hereby incorporated by reference in its entirety for all purposes.

### BACKGROUND OF THE INVENTION

Power electronics are widely used in a variety of applications, including power conversion, electric motor drives, switching power supplies, lighting, etc. Power electronic devices, such as transistors, are commonly used in such power switching applications. The operation of the present generation of power transistor devices, particularly with high voltage (>600V) handling capability, is hampered by slow switching speeds, and high specific on-resistance.

Thus, there is a need in the art for power transistor devices exhibiting low capacitance, a low, positive threshold voltage, and low specific on-resistance along with high breakdown voltage.

### SUMMARY OF THE INVENTION

The present invention generally relates to vertical field-effect transistor (FET) devices with an improved combination of lower-resistance gate routing and reduced gate-source capacitance. Merely by way of example, implementations of the present invention provide novel vertical FET devices and methods of fabricating such vertical FET devices with improved capacitance characteristics. The disclosure provided herein is not limited to vertical FETs and is applicable to a variety of electronic devices.

According to an embodiment of the present invention, a vertical FET device is provided. The vertical FET device includes a semiconductor structure comprising a semiconductor substrate, a first semiconductor layer coupled to the semiconductor substrate, and a second semiconductor layer coupled to the first semiconductor layer. The vertical FET device also includes a plurality of fins. Adjacent fins of the plurality of fins are separated by a trench extending into the second semiconductor layer and each of the plurality of fins includes a channel region disposed in the second semiconductor layer. The vertical FET device further includes a gate region extending into a sidewall portion of the channel region of each of the plurality of fins, a source metal structure coupled to the second semiconductor layer, a gate metal structure coupled to the gate region, and a drain contact coupled to the semiconductor substrate.

According to another embodiment of the present invention, a method for manufacturing a vertical FET device is provided. The method includes providing a semiconductor substrate, epitaxially growing a first semiconductor layer coupled to the semiconductor substrate, epitaxially growing a second semiconductor layer coupled to the first semiconductor layer, and forming a patterned hard mask coupled to the second semiconductor layer. The method also includes etching the second semiconductor layer and a portion of the first semiconductor layer to form a plurality of fins, applying a diffusion dopant layer, applying a sacrificial planarization layer on the diffusion dopant layer, and selectively etching the sacrificial planarization layer to expose the diffusion dopant layer. The method further includes removing exposed portion of the diffusion dopant layer and the sacrificial planarization layer, performing a thermal treatment to diffuse the diffusion dopant layer into the first semiconductor layer and form a diffused gate layer, removing the diffusion dopant layer and the patterned hard mask, forming a source metal structure coupled to a top surface of the second semiconductor layer, forming a gate metal structure coupled to the diffused gate layer, and forming a drain contact coupled to a bottom surface of the semiconductor substrate.

According to a specific embodiment of the present invention, a method for manufacturing a vertical FET device is provided. The method includes providing a semiconductor substrate, epitaxially growing a first semiconductor layer coupled to the semiconductor substrate, epitaxially growing a second semiconductor layer coupled to the first semiconductor layer, and forming a patterned hard mask coupled to the second semiconductor layer. The method also includes etching the second semiconductor layer and a portion of the first semiconductor layer to form a plurality of fins, implant a dopant to form a gate region, depositing a protective layer, and performing a thermal anneal to activate the dopant and form an implanted gate layer. The method further includes removing the protective layer and the patterned hard mask, forming a source metal structure coupled to a top surface of the second semiconductor layer, forming a gate metal structure coupled to the implanted gate layer, and forming a drain contact coupled to a bottom surface of the semiconductor substrate. In some embodiments, the method further includes forming an edge termination for the implanted gate layer overlaying a top surface of the first semiconductor layer. The dopant can include a p-type dopant. The implanted gate layer can extend along a portion of sidewalls of the second semiconductor layer. The drain contact can include titanium, aluminum, or a combination thereof.

According to a particular embodiment of the present invention, a method for manufacturing a conformal-gate vertical FET device is provided. The method includes providing a semiconductor structure including a substrate, a first semiconductor layer, and a second semiconductor layer and forming a plurality of fins having sidewall surfaces in a portion of the first semiconductor layer and the second semiconductor layer. The plurality of fins are separated by trenches. The method also includes growing a third semiconductor layer coupled to the sidewall surfaces of the plurality of fins. The third semiconductor layer includes a dopant and comprises a recessed gate region. The method also includes forming a source metal, a gate metal, and a drain contact.

Numerous benefits are achieved by way of the present invention over conventional techniques. For example, embodiments of the present invention provide vertical conduction channels that enable lower-resistance gate routing and reduced gate-source capacitance. The semiconductor devices provided by embodiments of the present invention may have shorter fins or more narrow channels as compared with conventional semiconductor devices, which may result in the ability to pinch off the channel at a lower threshold voltage. Embodiments of the present disclosure may additionally include gate regions that extend only partially up the sidewall of the fins, reducing the likelihood of an electrical short or unwanted leakage occurring in the semiconductor device. These and other embodiments of the invention, along with many of its advantages and features, are described in more detail in conjunction with the text below and attached figures.

### BRIEF DESCRIPTION OF THE DRAWINGS

FIGS. 1A-1E are cross-sectional diagrams illustrating stages of fabricating fins of a vertical FET device according to some embodiments of the present invention.

FIGS. 2A-2D are cross-sectional diagrams illustrating stages of forming a diffused gate by solid-phase diffusion in a vertical FET device according to some embodiments of the present invention.

FIGS. 3A-3D are cross-sectional diagrams illustrating finishing stages of a method for manufacturing a vertical FET device according to some embodiments of the present invention.

FIG. 4 is a flowchart illustrating a method for fabricating a vertical FET device with a diffused gate layer.

FIGS. 5A-5J are cross-sectional diagrams illustrating stages of fabricating a diffused-gate vertical FET according to some embodiments of the present invention.

FIG. 6 is a flowchart illustrating a method for fabricating a diffused-gate vertical FET according to some embodiments of the present disclosure.

FIGS. 7A-7E are cross-sectional diagrams illustrating stages of forming a conformal layer on fins of a vertical FET according to some embodiments of the present disclosure.

FIGS. 8A-8C are cross-sectional diagrams illustrating stages of fabricating a diffused-gate vertical FET by solid-phase diffusion according to some embodiments of the present disclosure.

FIG. 9 is a flowchart illustrating a method for fabricating a diffused-gate vertical FET by solid-phase diffusion according to some embodiments of the present disclosure.

FIG. 10 is a cross-sectional diagram illustrating fabrication of a diffused-gate vertical FET by gas-phase diffusion according to some embodiments of the present disclosure.

FIG. 11 is a flowchart illustrating a method for fabricating a diffused-gate vertical FET by gas-phase diffusion according to some embodiments of the present disclosure.

FIGS. 12A-12E are cross-sectional diagrams illustrating an example of fabricating an implanted-gate vertical FET according to some embodiments of the present disclosure.

FIG. 13 is a flowchart illustrating a method for fabricating an implanted-gate vertical FET according to some embodiments of the present disclosure.

FIGS. 14A-14B are cross-sectional diagrams illustrating another example of fabricating an implanted-gate vertical FET according to some embodiments of the present disclosure.

FIG. 15 is a flowchart illustrating another method for fabricating an implanted-gate vertical FET according to some embodiments of the present disclosure.

FIG. 16 is a cross-sectional diagram illustrating fabrication of a conformal epitaxial gate vertical FET according to some embodiments of the present disclosure.

FIG. 17 is a flowchart illustrating a method for fabricating a conformal epitaxial gate vertical FET according to some embodiments of the present disclosure.

FIG. 18 is a cross-sectional diagram illustrating fabrication of another example of a conformal epitaxial gate vertical FET according to some embodiments of the present disclosure.

FIG. 19 is a flowchart illustrating another method for fabricating a conformal epitaxial gate vertical FET according to some embodiments of the present disclosure.

### DETAILED DESCRIPTION OF SPECIFIC EMBODIMENTS

Embodiments of the present disclosure will be described more fully hereinafter with reference to the accompanying drawings. The disclosure may, however, be embodied in many different forms and should not be construed as limited to the embodiments set forth herein. Rather, these embodiments are provided so that this disclosure will be thorough and complete, and will fully convey the scope of the invention to those skilled in the art. The features may not be drawn to scale, some details may be exaggerated relative to other elements for clarity. Like numbers refer to like elements throughout.

Embodiments of the present invention relate to vertical-fin-based field effect transistor (FET) devices. More particular, embodiments of the present invention relate to a vertical FET device with improved routing resistance, reduced lithography requirements, and improved voltage characteristics. Merely by way of example, embodiments of the present invention relate to a vertical FET, devices including vertical FETs, and methods for manufacturing such vertical FET devices.

Embodiments of the present disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. In the following drawings, the bottom portion of the fins are shown as having a 90 degrees angle with the surface of the graded doping region, i.e., the fins are shown as having a cross-sectional rectangular shape. It is understood that the bottom portion of the fins may have rounded or curved features. Thus, the regions illustrated in the figures are schematic in nature and their shapes are not intended to illustrate the actual shape of a region of a device and are not intended to limit the scope of the invention.

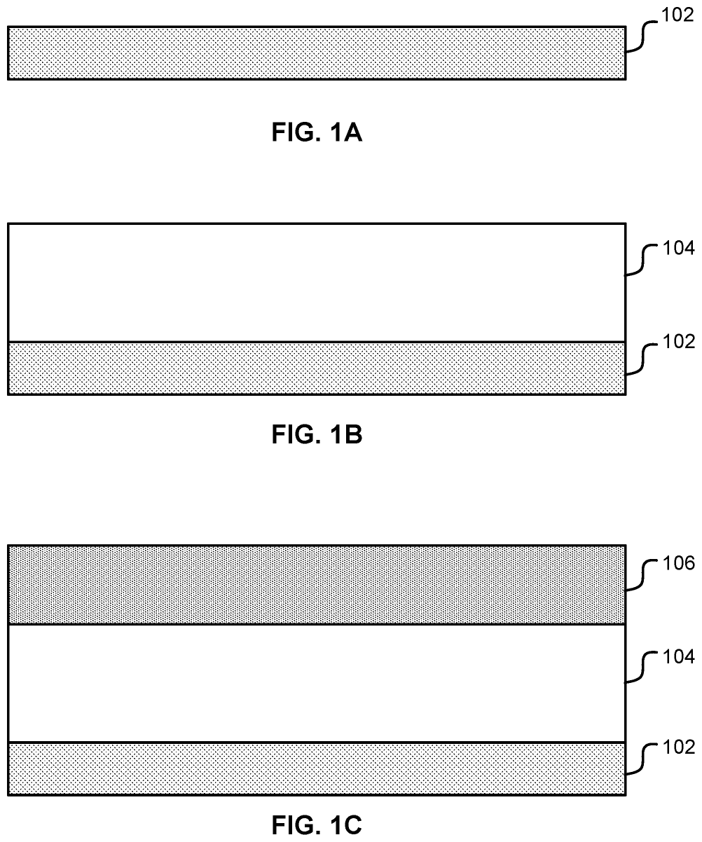

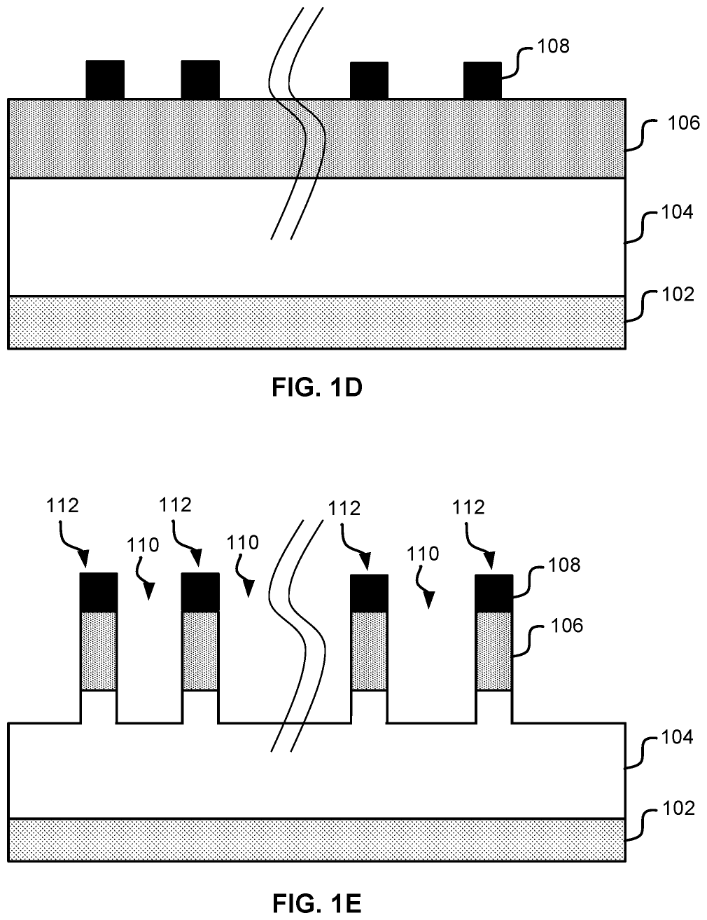

FIGS. 1A-1E are cross-sectional diagrams illustrating stages of fabricating fins of a vertical FET device according to some embodiments of the present invention. Referring to FIG. 1A, a III-nitride substrate 102 is provided. The III-nitride substrate 102 can be a N+ GaN substrate having a resistivity of approximately 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Referring to FIG. 1B a first III-nitride epitaxial layer 104 can be formed on the III-nitride substrate 102. The first III-nitride epitaxial layer 104 can be 5-12 μm thick, or in some embodiments 1-5 μm thick (e.g., suitable for use in 50 V-500 V applications), or in other embodiments 12-30 μm thick (e.g., suitable for use in 1.7 kV-5 kV applications). The first III-nitride epitaxial layer 104 can be epitaxially grown on the III-nitride substrate 102 at a temperature between 950 and 1100° C. and can be characterized by a first dopant concentration (e.g., N-type doping with a dopant concentration of approximately 1×10¹⁶ atoms/cm³). In some embodiments, the first III-nitride epitaxial layer 104 can be a drift layer including a uniformly doped region (layer) on the III-nitride substrate 102 and a graded doping region (layer) on the uniformly doped region. In an embodiment, the uniformly doped region can have a thickness of about 10.5 μm, and the graded doping region can have a thickness of about 0.3 μm. In an embodiment, the surface of the III-nitride substrate 102 can be miscut from the c-plane at an angle to facilitate high-quality epitaxial growth for high-voltage operation of the drift layer.

Referring to FIG. 1C, a second III-nitride epitaxial layer 106 can be formed on the first III-nitride epitaxial layer 104. In an embodiment, the second III-nitride epitaxial layer 106 can be epitaxially grown on the first III-nitride epitaxial layer 104 with a thickness of about 0.7-0.9 μm and can be characterized by a second dopant concentration (e.g., N-type doping). The second dopant concentration may be higher than the first dopant concentration in some embodiments. In an embodiment, the second dopant concentration is about 1.3×10¹⁷ atoms/cm³. In an embodiment, the second III-nitride epitaxial layer 106 has a more highly doped surface layer (e.g., 1-3×10¹⁸ atoms/cm³), with a thickness of 30-100 nm.

Referring to FIG. 1D, a patterned hard mask 108 can be formed and patterned on the second III-nitride epitaxial layer 106. In some embodiments, the patterned hard mask 108 may be a dielectric material such as silicon nitride, silicon dioxide, silicon oxynitride, silicon-aluminum nitride, or the like. The dielectric material may be deposited by low-pressure chemical vapor deposition (LPCVD), plasma-enhanced chemical vapor deposition (PECVD), atomic-layer deposition (ALD), or the like. In some embodiments, the patterned hard mask 108 is a composite hard mask including a metal layer on the second III-nitride epitaxial layer 106 and a dielectric hard mask layer on the metal layer. In some embodiments, the metal layer is a refractory metal, refractory metal alloy, or refractory metal nitride (e.g., TiN). The patterned hard mask 108 may be patterned using photolithography in combination with a reactive-ion-etch (RIE) process. In some embodiments utilizing a composite hard mask, the dielectric hard mask layer is first patterned, and then the patterned dielectric hard mask is used as a hard mask to pattern the metal layer.

Referring to FIG. 1E, a recess region 110, also referred to as a trench, can be formed in the second III-nitride epitaxial layer 106 using the patterned hard mask 108 and an etch process (e.g., an RIE process). The etching process can form recess region 110 such that adjacent fins 112 are separated by trenches corresponding to recess region 110. In an embodiment, the recess region 110 can extend into the first III-nitride epitaxial layer 104. In an embodiment, the etched recess extends partially (e.g., 0.1 μm) into the graded layer at the top of the first III-nitride epitaxial layer 104. In an embodiment, the recess region 110 can remain inside the second III-nitride epitaxial layer 106.

In one embodiment, after forming the fins 112, a cleaning process is carried using a tetramethylammonium hydroxide (TMAH) solution of about 25% by weight, at a temperature of about 85° C., and for a duration of about 30 minutes. In another embodiment, prior to performing a cleaning using the TMAH solution, a pre-cleaning such as piranha clean using a H₂SO₄:H₂O in a volume ratio 2:1 for 2 minutes may also be performed.

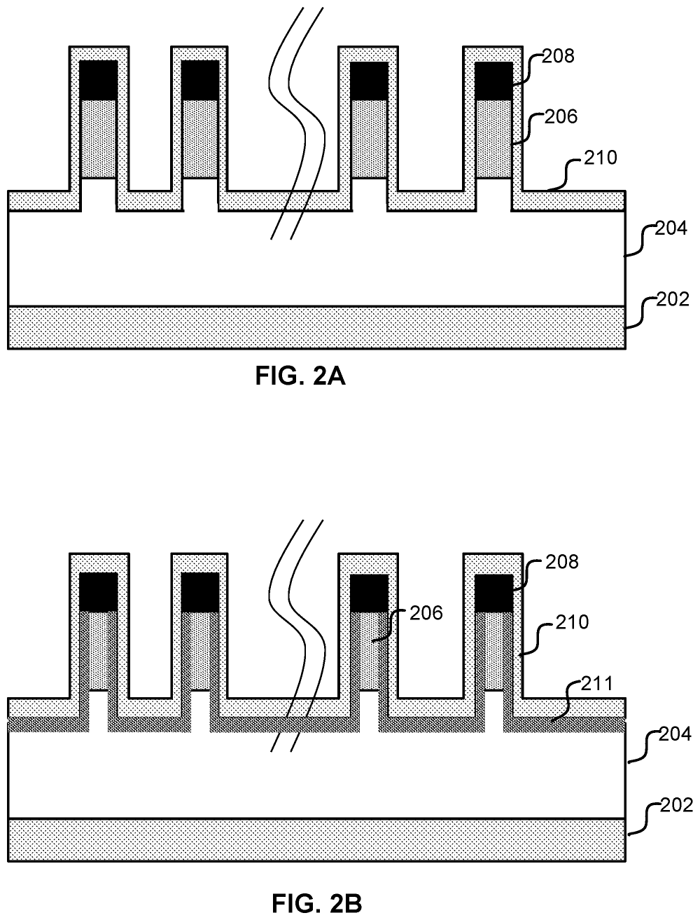

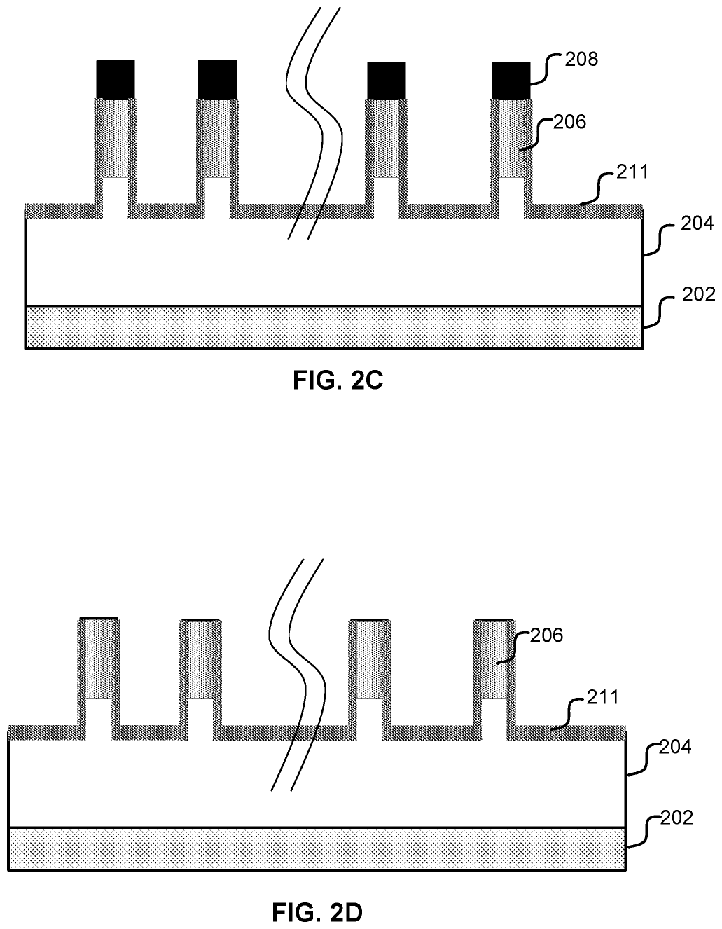

FIGS. 2A-2D are cross-sectional diagrams illustrating stages of forming a diffused gate by solid-phase diffusion in a vertical FET device according to some embodiments of the present invention. The stages may be performed subsequent to the stages illustrated in FIGS. 1A-1E. Referring to FIG. 2A, a layer of a diffusion dopant material 210 can be applied to surfaces of the fins, the trenches between fins, and the patterned hard mask 208. In some embodiments, the layer of diffusion dopant material 210 may include either a metal layer formed with a p-type dopant (e.g., Mg, Zn, combinations thereof, and the like) or a metallic oxide layer formed with a p-type dopant (e.g., MgO, ZnO, combinations thereof, and the like), in contact with the exposed III-nitride surfaces of the fins. In some embodiments, the thickness of the metal or metallic oxide layer is 50-100 nm. In some embodiments, the layer of diffusion dopant material 210 may further include a second layer of dielectric material (e.g., SiO₂, Si₃N₄ or the like) disposed on the metal or metallic oxide layer.

Referring to FIG. 2B, a thermal treatment can be performed to diffuse the diffusion dopant material 210 into the exposed surfaces of the first III-nitride layer 204 and the second III-nitride layer 206. The first III-nitride layer 204 can be coupled to a III-nitride substrate 202. In some embodiments utilizing a p-type dopant as the diffusion dopant material 210, thermal diffusion can form a diffused p-GaN gate region 211. In some embodiments, the thermal treatment may be performed in a furnace at temperatures from 900° C. to 1100° C. In some embodiments, the thermal treatment may be performed in a rapid thermal annealer at temperatures from 1000° C. to 1450° C. In some embodiments the thermal treatment may be performed at a high ambient pressure (e.g., at 1 GPa in a N₂ ambient), with or without the protective layer. In some embodiments the heating may be a result of a series of rapid pulses (e.g. microwave). In some embodiments, the diffused p-GaN gate region 211 has a junction depth between 25 and 50 nm. In some embodiments, the diffused p-GaN gate region 211 has a junction depth between 50 and 100 nm. The p-GaN gate region 211 is along the channel length as well as a portion of the drift layer, which may allow for shorter fins. The p-GaN gate region 211 can provide a doping gradient that may be useful in breakdown and rounded corners to reduce edge effects. In an embodiment, the dopant metallurgical concentration at the interface between the diffusion dopant material and the III-nitride semiconductor layers is 1-3×10¹⁹ atoms/cm³.

Referring to FIG. 2C, the diffusion dopant material 210 can be removed. In some embodiments, the removal is performed using a wet etch. The diffused p-GaN gate region 211 can be exposed when the diffusion dopant material 210 is removed.

Referring to FIG. 2D, the patterned hard mask 208 can be removed. In one embodiment, the patterned hard mask 208 is removed using wet or dry etch processes. In one embodiment, if a metal layer is used as part of the patterned hard mask 208, the metal layer is left in place to serve as a contact to second semiconductor layer.

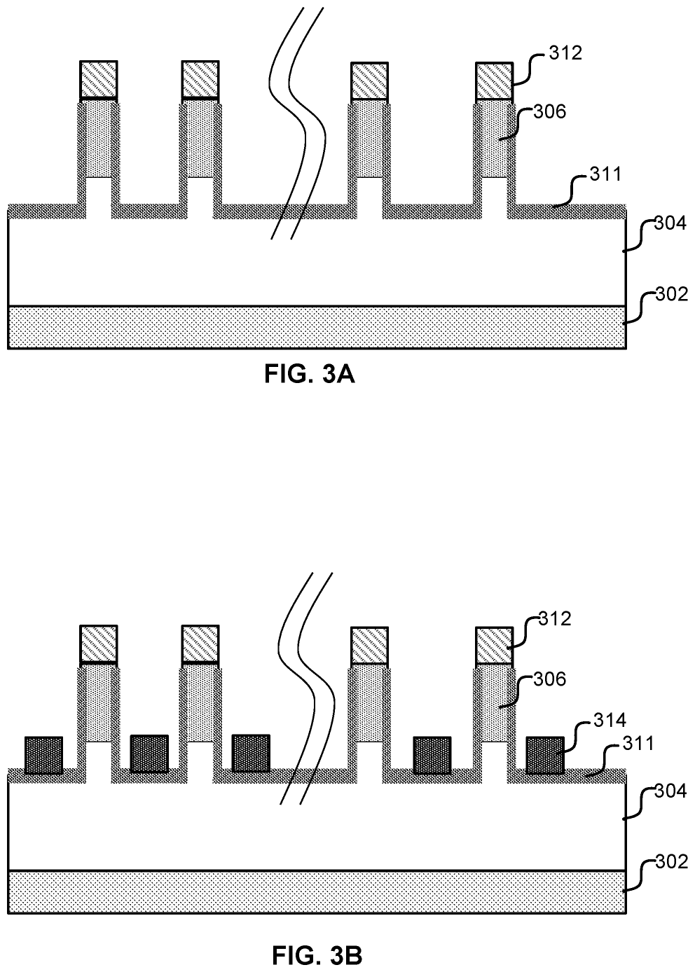

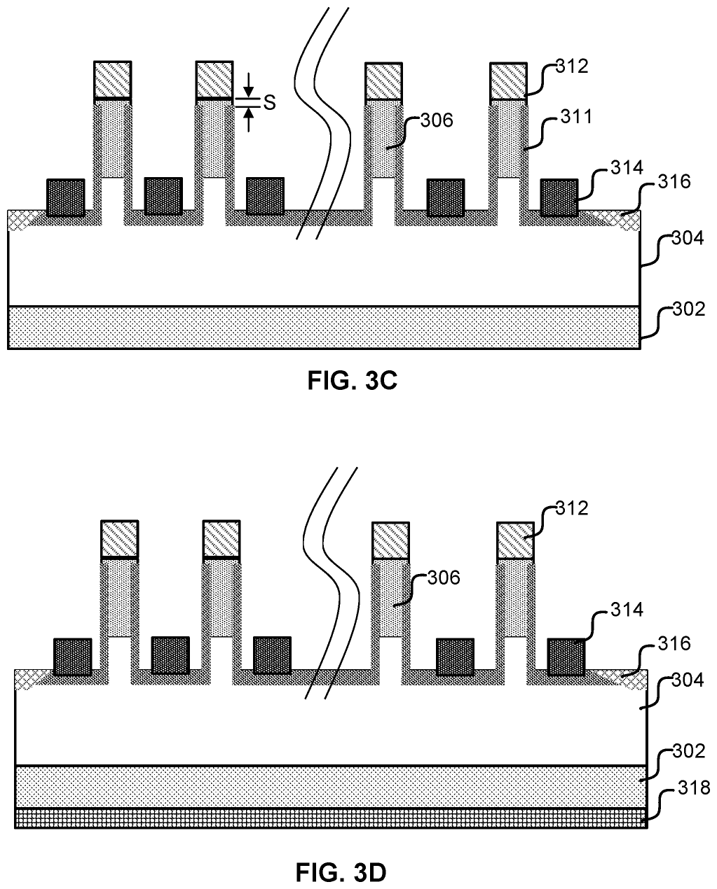

FIGS. 3A-3D are cross-sectional diagrams illustrating finishing stages of a method for manufacturing a vertical FET device according to some embodiments of the present invention. The stages may be performed after the stages illustrated in FIGS. 1A-1E and FIGS. 2A-2D. Referring to FIG. 3A, a source metal contact structure 312 can be formed on an upper portion of the second III-nitride layer 306, which is coupled to a first III-nitride layer 304. In other words, source metal contact structure 312 can be formed on the fins. Source metal contact structure 312 is electrically isolated from the gate regions as described herein. As an example, as illustrated in FIG. 3C, in which semiconductor gate region 311 extends along the sidewall of the fin, a physical separation S between semiconductor gate region 311 and source metal contact structure 312 can be utilized to provide electrical isolation. In some embodiments, the source metal contact structure 312 forms a self-aligned contact to the upper portion of second III-nitride layer 306. In some embodiments, the source metal contact structure 312 includes a hard mask metal layer. The source metal contact structure 312 may include titanium, aluminum, combinations thereof, or the like.

Referring to FIG. 3B, a gate metal contact structure 314 is formed on the upper portion of semiconductor gate region 311. In some embodiments, the gate metal contact structure 314 can include a metallic structure. For example, the metallic structure may include nickel, palladium, silver, gold, combinations thereof, and the like. The metallic structure can make an ohmic contact with the semiconductor gate region 311, which can be a p-type semiconductor gate region.

Referring FIG. 3C, an edge termination 316 is formed on the p-type layer used as the semiconductor gate region 311 to enable high-voltage operation of the device. The p-type layer may also be connected to the source in some embodiments.

Referring to FIG. 3D, a drain metal contact structure 318 is formed on a second side, i.e., the backside, of III-nitride substrate 302. The drain metal contact structure 318 can form an ohmic contact to the III-nitride substrate 302. In some embodiments, the drain metal contact structure 318 can include titanium, aluminum, or combinations thereof. In some embodiments, the drain metal contact structure 318 can further include a solderable metal structure such as silver, lead, tin, combinations thereof, or the like.

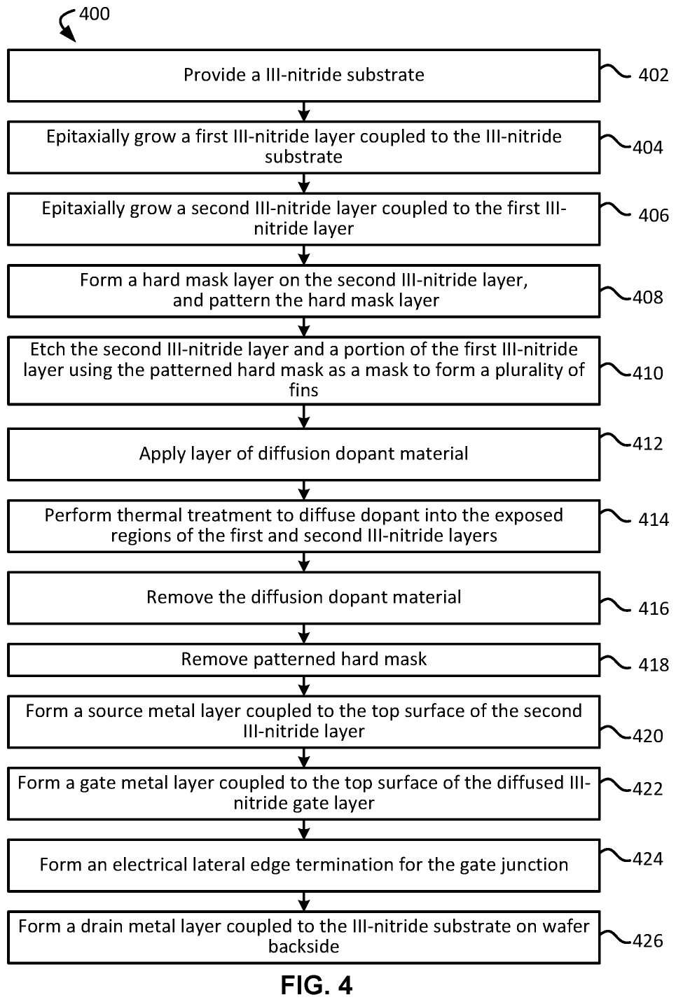

FIG. 4 is a flowchart illustrating a method for fabricating a vertical FET device with a diffused gate layer. A III-nitride substrate is provided (402). In an embodiment, the III-nitride substrate is an N+ GaN substrate having a resistivity in a range of about 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Method 400 also includes forming a first III-nitride epitaxial layer, for example, a 5-12 μm thick first III-nitride epitaxial layer (e.g., an N− GaN epitaxial layer deposited on the III-nitride substrate (404)). The first III-nitride epitaxial layer is epitaxially grown on the III-nitride substrate at a temperature between 950 and 1100° C. and is characterized by a first dopant concentration, e.g., N-type doping with a dopant concentration of about 1×10¹⁶ atoms/cm³. In some embodiments, the first III-nitride epitaxial layer is a drift layer including a uniformly doped region (layer) on the III-nitride substrate and a graded doping region (layer) on the uniformly doped region. In an embodiment, the uniformly doped region has a thickness of about 10.5 μm, and the graded doping region has a thickness of about 0.3 μm. In an embodiment, the surface of substrate is miscut from the c-plane at an angle to facilitate high-quality epitaxial growth for high-voltage operation of the drift layer.

Method 400 further includes forming a second III-nitride epitaxial layer on the first III-nitride epitaxial layer (406). In an embodiment, the second III-nitride epitaxial layer is epitaxially grown on the first III-nitride epitaxial layer with a thickness of about 0.7-0.9 μm and is characterized by a second dopant concentration, e.g., N-type doping. The second dopant concentration is higher than the first dopant concentration in some embodiments. In an embodiment, the second dopant concentration is about 1.3×10¹⁷ atoms/cm³. In an embodiment, the second III-nitride epitaxial layer has a more highly doped surface layer, e.g., about 1-3×10¹⁸ atoms/cm³, with a thickness of 30-100 nm.

Method 400 further includes forming and patterning a hard mask layer on the second III-nitride epitaxial layer (408). In some embodiments, the hard mask layer may be a dielectric material such as silicon nitride, silicon dioxide, silicon oxynitride, silicon-aluminum nitride or the like. The dielectric material may be deposited by LPCVD, PECVD, ALD or the like. In some embodiments, the hard mask layer is a composite hard mask including a metal layer on the second III-nitride epitaxial layer and a dielectric hard mask layer on the metal layer. In some embodiments, the metal layer is a refractory metal, refractory metal alloy, or refractory metal nitride (e.g., TiN). The hard mask layer may be patterned using photolithography in combination with an RIE process. In some embodiments utilizing a composite hard mask, the dielectric hard mask layer is first patterned, and then the patterned dielectric hard mask is used as a hard mask to pattern the metal layer.

Method 400 further includes forming a recess region in the second III-nitride epitaxial layer using the patterned hard mask and an etch process, e.g., an RIE process (410). In an embodiment, the etched recess extends into the first III-nitride epitaxial layer to form fins separated by trenches. In an embodiment, the etched recess extends partially (e.g., 0.1 μm) into the graded layer at the top of the first III-nitride epitaxial layer. In an embodiment, the etch process further includes a wet etch process (e.g., using a TMAH solution of about 25% by weight, at a temperature of about 85° C., and for a duration of about 30 minutes) that can anisotropically etch the III-nitride layers. In another embodiment, prior to performing an etch step using the TMAH solution, a pre-cleaning such as piranha clean using a H₂SO₄:H₂O in a volume ratio 2:1 for 2 minutes may also be performed.

Method 400 further includes applying a layer of a diffusion dopant material to the surfaces of the fins and the patterned hard mask (412). In some embodiments, the layer of diffusion dopant material may include either a metal layer formed with a p-type dopant (e.g., Mg, Zn, combinations thereof, and the like) or a metallic oxide layer formed with a p-type dopant (e.g., MgO, ZnO, combinations thereof, and the like), in contact with the exposed III-nitride surfaces of the fins. In some embodiments, the thickness of the metal or metallic oxide layer is 50-100 nm. In some embodiments, the layer of diffusion dopant material may further include a second layer of dielectric material (e.g., SiO₂, Si₃N₄ or the like) disposed on the metal or metallic oxide layer.

Method 400 further includes performing a thermal treatment to diffuse the p-type dopant into the exposed surfaces of the first and second III-nitride semiconductor layers (414). The resulting channel can have a width of the fin width minus twice the diffusion depth. In some embodiments, the thermal treatment may be performed in a furnace at temperatures from 900° C. to 1100° C. In some embodiments, the thermal treatment may be performed in a rapid thermal annealer at temperatures from 1000° C. to 1450° C. In some embodiments the thermal treatment may be performed at a high ambient pressure (e.g., at 1 GPa in a N₂ ambient), with or without the protective layer. In some embodiments the heating may be a result of a series of rapid pulses (e.g. microwave).

Method 400 further includes removal of the diffusion dopant material (416). In some embodiments, the removal is performed using a wet etch.

Method 400 further includes removing the patterned hard mask on the top surface of the second III-nitride layer (418). In some embodiments where a composite hard mask layer is used, the top dielectric layer may be removed, leaving the metal layer.

Method 400 further includes forming a source contact structure on the top surface of the second III-nitride layer (420). In some embodiments, the metal hard mask layer is left in place, and the source contact structure is formed on top of the metal hard mask layer. In some embodiments, the source contact structure is formed using titanium and aluminum.

Method 400 further includes forming a forming a gate contact structure on that exposed surface portion of the diffused gate layer overlaying the top surface of the first III-nitride epitaxial layer (422). The gate contact structure may include nickel, gold, palladium, platinum, molybdenum, and the like.

The resulting structure resulting from method 400 can present various advantages. For example, the gate contact structure can be recessed, which may allow for thicker metallization. As a result, the routing resistance can be reduced. Additionally, a portion of the channel can extend below the etch interface of the second III-nitride epitaxial layer and the first III-nitride epitaxial layer, which may allow for shorter fins. Starting with lithographic size constraints and diffusing the gate into the structure can lead to a narrower channel, can be pinched off at a lower threshold voltage. In addition, the fins can be made wider, which can reduce lithography requirements of the fins. This may also increase the ability to align the source contact to the fin.

Additionally, for enhancement mode devices, the fin width can be small and utilize light doping. For example, enhancement mode devices can have a fin width of 0.5 μm with doping of approximately 10¹⁶ dopants/cm³. The resulting structure resulting from method 400 can include fin widths of 0.2 μm with doping of approximately 10¹⁷ dopants/cm³ and threshold voltages in the range of 0.5 V-1.8 V. As a result, the performance of enhancement mode devices can be increased in comparison with conventional devices.

Method 400 further includes forming a junction-terminated edge (“edge termination”) for the p-GaN layer at the lateral edges of the device active region (424). In some cases, the p-GaN layer is connected to the gate, in others to the source. In some embodiments, this edge termination is formed using a tapered junction.

Method 400 further includes forming a drain contact at the bottom side of the substrate by forming a metallic contact to the bottom side of substrate (426).

It should be appreciated that the specific steps illustrated in FIG. 4 provide a particular method of fabricating a vertical FET device with a diffused gate layer according to an embodiment of the present invention. Other sequences of steps may also be performed according to alternative embodiments. For example, alternative embodiments of the present invention may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular application. One of ordinary skill in the art would recognize many variations, modifications, and alternatives.

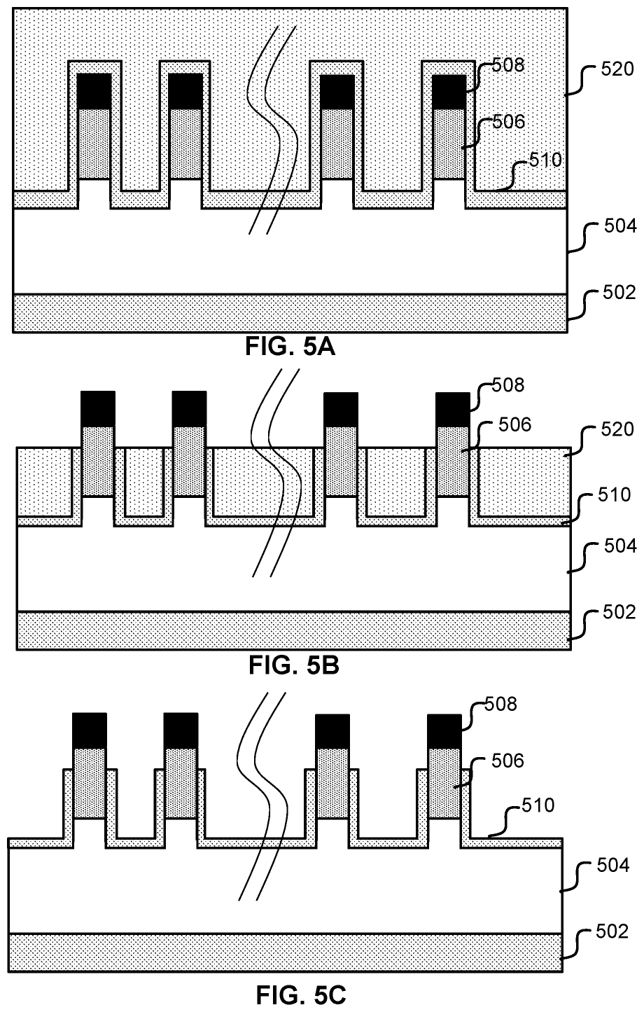

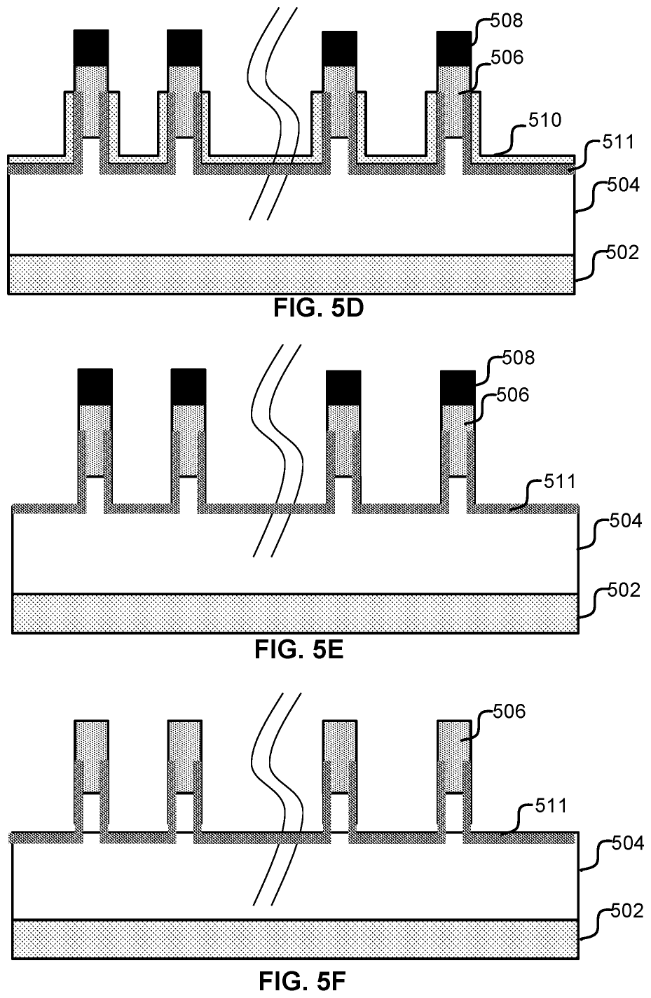

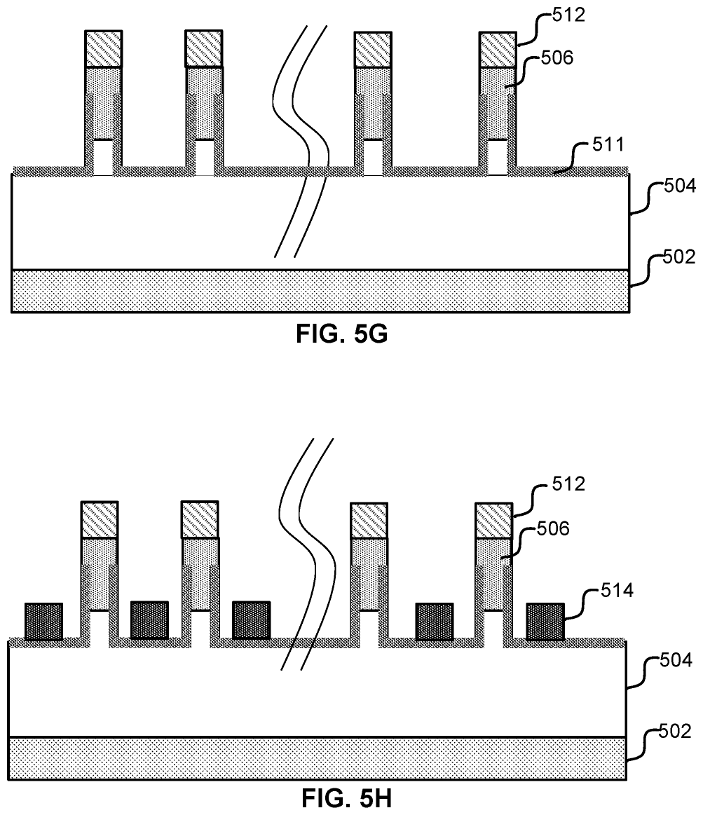

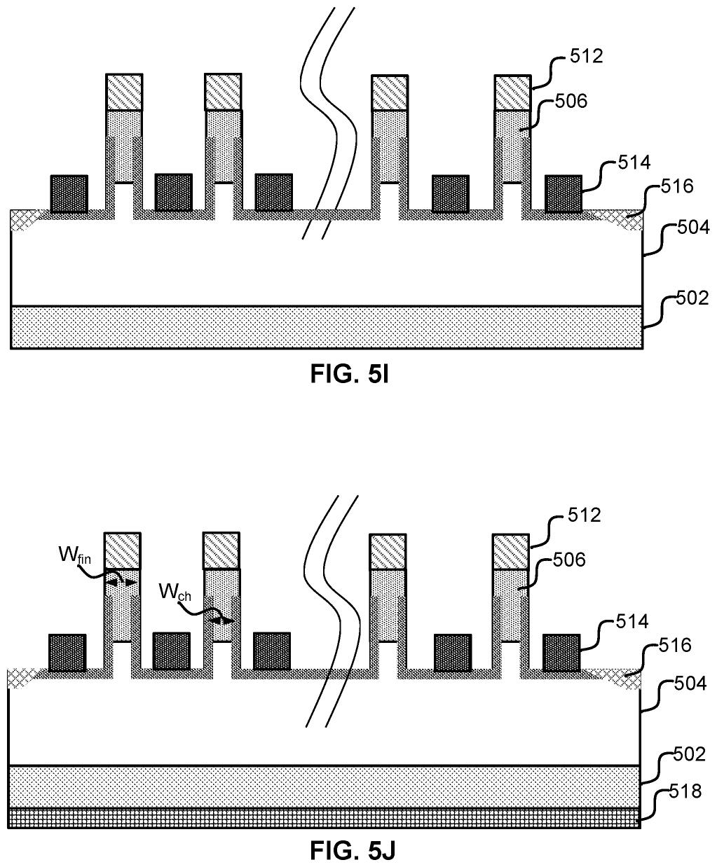

FIGS. 5A-5J are cross-sectional diagrams illustrating stages of fabricating a diffused-gate vertical FET according to some embodiments of the present invention. The stages may be performed subsequent to the stages illustrated in FIGS. 1A-1E and FIG. 2A.

Referring to FIG. 5A, a sacrificial planarization material 520 is applied to fill in the trenches and provide a substantially planar surface above the fins. In some embodiments, the sacrificial planarization material 520 is a polymer that acts as a spacer structure. In some embodiments, the sacrificial planarization material 520 is a photoresist. In some embodiments, the sacrificial planarization material is a spin-on glass.

Referring to FIG. 5B, the sacrificial planarization material 520 can be etched back to expose a portion of the diffusion dopant material 510 on the sidewall of the fins. The exposed portion of the diffusion dopant material 510 may be controlled by the etch depth of the etchback. After the etchback, the exposed diffusion dopant material 510 may be selectively removed. Only a portion of the second III-nitride layer 506 used to form the channel may be doped with the diffusion dopant material 510. In this manner, the height of the diffusion dopant material 510 on the sidewall may be controlled to a height less than that of the fin sidewall. This may reduce the likelihood of a short or high leakage path occurring between the channel and a source metal contact structure 512 illustrated in FIG. 5G.

Referring to FIG. 5C, the sacrificial planarization material 520 can be removed. For example, if the sacrificial planarization material 520 is a polymer or photoresist, an oxygen plasma may be used to remove the sacrificial planarization material 520.

Referring to FIG. 5D, a thermal treatment can be performed to diffuse the dopant into the exposed surfaces of the first III-nitride layer 504 and the second III-nitride layer 506. In some embodiments, the thermal treatment may be performed in a furnace at temperatures from 900° C. to 1100° C. In some embodiments, the thermal treatment may be performed in a rapid thermal annealer at temperatures from 1000° C. to 1450° C. In some embodiments the thermal treatment may be performed at a high ambient pressure (e.g., at 1 GPa in a N₂ ambient), with or without the protective layer. In some embodiments the heating may be a result of a series of rapid pulses (e.g. microwave).

Referring to FIG. 5E, the diffusion dopant material 510 can be removed to expose the diffused gate region 511, which be a p-GaN diffused gate region, on the surfaces of the fins. In some embodiments, the removal is performed using a wet etch.

Referring to FIG. 5F, the patterned hard mask 508 can be removed. In one embodiment, the patterned hard mask 508 is removed using wet or dry etch processes. In one embodiment, if a metal layer is used as part of the patterned hard mask 508, the metal layer is left in place to serve as a contact to second semiconductor layer.

Referring to FIG. 5G, a source metal contact structure 512 can be formed on an upper portion of the second III-nitride layer 506. In other words, source metal contact structure 512 can be formed on the fins. In some embodiments, the source metal contact structure 512 forms a self-aligned contact to the upper portion of second III-nitride layer 506. In some embodiments, the source metal contact structure 512 includes a hard mask metal layer. The source metal contact structure 512 may include titanium and aluminum.

Referring to FIG. 5H, a gate metal contact structure 514 is formed on the upper portion of semiconductor gate layer. In some embodiments, the gate metal contact structure 514 can include a metallic structure. For example, the metallic structure may include nickel, palladium, silver, gold, the combination thereof, and the like. The metallic structure can make an ohmic contact with the p-type semiconductor gate layer.

Referring to FIG. 5I, an edge termination 516 is formed on the semiconductor gate layer to enable high-voltage operation of the device.

Referring to FIG. 5J, a drain metal contact structure 518 is formed on a second side of III-nitride substrate 502. The drain metal contact structure 518 can form an ohmic contact to the III-nitride substrate 502. In some embodiments, the drain metal contact structure 318 can include titanium, aluminum, or combinations thereof. In some embodiments, the drain metal contact structure 518 can further include a solderable metal structure such as silver, lead, tin, combinations thereof, or the like. The fin width is represented in FIG. 5J as W_{fin}, which is larger than the channel width, which is represented as W_{ch}. This is because the diffusion dopant material 510 diffused into the fin and narrowed the channel.

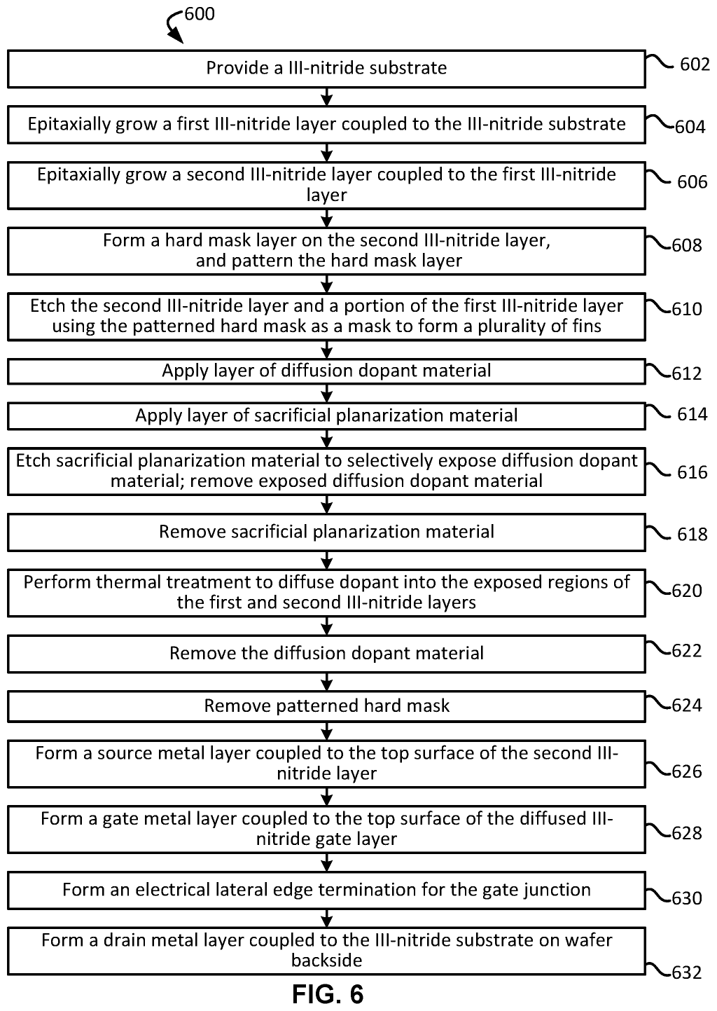

FIG. 6 is a flowchart illustrating a method for fabricating a diffused-gate vertical FET according to some embodiments of the present disclosure. A III-nitride substrate is provided (602). In an embodiment, the III-nitride substrate is an N+ GaN substrate having a resistivity in a range of about 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Method 600 also includes forming a first III-nitride epitaxial layer, for example, a 5-12 μm thick first III-nitride epitaxial layer (e.g., an N− GaN epitaxial layer deposited on the III-nitride substrate (604). The first III-nitride epitaxial layer is epitaxially grown on the III-nitride substrate at a temperature between 950 and 1100° C. and is characterized by a first dopant concentration, e.g., N-type doping with a dopant concentration of about 1×10¹⁶ atoms/cm³. In some embodiments, the first III-nitride epitaxial layer is a drift layer including a uniformly doped region (layer) on the III-nitride substrate and a graded doping region (layer) on the uniformly doped region. In an embodiment, the uniformly doped region has a thickness of about 10.5 μm, and the graded doping region has a thickness of about 0.3 μm. In an embodiment, the surface of substrate is miscut from the c-plane at an angle to facilitate high-quality epitaxial growth for high-voltage operation of the drift layer.

Method 600 further includes forming a second III-nitride epitaxial layer on the first III-nitride epitaxial layer (606). In an embodiment, the second III-nitride epitaxial layer is epitaxially grown on the first III-nitride epitaxial layer with a thickness of about 0.7-0.9 μm and is characterized by a second dopant concentration, e.g., N-type doping. The second dopant concentration is higher than the first dopant concentration in some embodiments. In an embodiment, the second dopant concentration is about 1.3×10¹⁷ atoms/cm³. In an embodiment, the second III-nitride epitaxial layer has a more highly doped surface layer, e.g., about 1-3×10¹⁸ atoms/cm³, with a thickness of 30-100 nm.

Method 600 further includes forming and patterning a hard mask layer on the second III-nitride epitaxial layer (608). In some embodiments, the hard mask layer may be a dielectric material such as silicon nitride, silicon dioxide, silicon oxynitride, silicon-aluminum nitride or the like. The dielectric material may be deposited by LPCVD, PECVD, ALD or the like. In some embodiments, the hard mask layer is a composite hard mask including a metal layer on the second III-nitride epitaxial layer and a dielectric hard mask layer on the metal layer. In some embodiments, the metal layer is a refractory metal, refractory metal alloy, or refractory metal nitride (e.g., TiN). The hard mask layer may be patterned using photolithography in combination with an RIE process. In some embodiments with a composite hard mask, the dielectric hard mask layer is first patterned, and then the patterned dielectric hard mask is used as a hard mask to pattern the metal layer.

Method 600 further includes forming a recess region in the second III-nitride epitaxial layer using the patterned hard mask by an etch process, e.g., an RIE process (610). In an embodiment, the etched recess extends into the first III-nitride epitaxial layer to define fins separated by trenches. In an embodiment, the etched recess extends partially (e.g., 0.1 μm) into the graded layer at the top of the first III-nitride epitaxial layer.

Method 600 further includes applying a layer of a diffusion dopant material to the surfaces of the fins and the patterned hard mask (612). In some embodiments, the layer of diffusion dopant material may include either a metal layer formed with a p-type dopant (e.g., Mg, Zn, combinations thereof, and the like) or a metallic oxide layer formed with a p-type dopant (e.g., MgO, ZnO, combinations thereof, and the like), in contact with the exposed III-nitride surfaces of the fins. In some embodiments, the thickness of the metal or metallic oxide layer is 50-100 nm. In some embodiments, the layer of diffusion dopant material may further include a second layer of dielectric material (e.g., SiO₂, Si₃N₄ or the like) disposed on the metal or metallic oxide layer.

Method 600 further includes applying a sacrificial planarization material (614) to fill in the trenches and provide a substantially planar surface above the fins. In some embodiments, the sacrificial planarization material is a polymer. In some embodiments, the sacrificial planarization material is a photoresist. In some embodiments, the sacrificial planarization material is a spin-on glass.

Method 600 further includes etching back the sacrificial planarization material (616) to expose a portion of the diffusion dopant material on the sidewall of the fins. The exposed portion of the diffusion dopant material may be controlled by the etch depth of the etchback. After the etchback, the exposed diffusion dopant material may be selectively removed (616). In this manner, the height of the diffusion dopant material on the sidewall may be controlled to a height less than that of the fin sidewall.

Method 600 further includes removing the sacrificial planarization material (618). For example, if the sacrificial planarization material is a polymer or photoresist, an oxygen plasma may be used to remove the sacrificial planarization material.

Method 600 further includes performing a thermal treatment to diffuse the p-type dopant into the exposed surfaces of the first and second III-nitride semiconductor layers (620). In some embodiments, the thermal treatment may be performed in a furnace at temperatures from 900° C. to 1100° C. In some embodiments, the thermal treatment may be performed in a rapid thermal annealer at temperatures from 1000° C. to 1450° C. In some embodiments the thermal treatment may be performed at a high ambient pressure (e.g., at 1 GPa in a N₂ ambient), with or without the protective layer. In some embodiments the heating may be a result of a series of rapid pulses (e.g. microwave).

Method 600 further includes removal of the diffusion dopant material (622). In some embodiments, the removal is performed using a wet etch.

Method 600 further includes removing the patterned hard mask on the top surface of the second III-nitride layer (624). In some embodiments where a composite hard mask layer is used, the top dielectric layer may be removed, leaving the metal layer.

Method 600 further includes forming a source contact structure on the top surface of the second III-nitride layer (626). In some embodiments, the metal hard mask layer is left in place, and the source contact structure is formed on top of the metal hard mask layer. In some embodiments, the source contact structure is formed using titanium and aluminum.

Method 600 further includes forming a forming a gate contact structure on that exposed surface portion of the diffused gate layer overlaying the top surface of the first III-nitride epitaxial layer (628). The gate contact structure may include nickel, gold, palladium, platinum, molybdenum, and the like.

Method 600 further includes forming a junction-terminated edge (“edge termination”) for the p-GaN layer at the lateral edges of the device active region (630). In some cases, the p-GaN layer is connected to the gate, in others to the source. In some embodiments, this edge termination is formed using a tapered junction.

Method 600 further includes forming a drain contact at the bottom side of the substrate by forming a metallic contact to the bottom side of substrate (632).

It should be appreciated that the specific steps illustrated in FIG. 6 provide a particular method of fabricating a vertical FET device with a diffused gate layer according to an embodiment of the present invention. Other sequences of steps may also be performed according to alternative embodiments. For example, alternative embodiments of the present invention may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular application. One of ordinary skill in the art would recognize many variations, modifications, and alternatives.

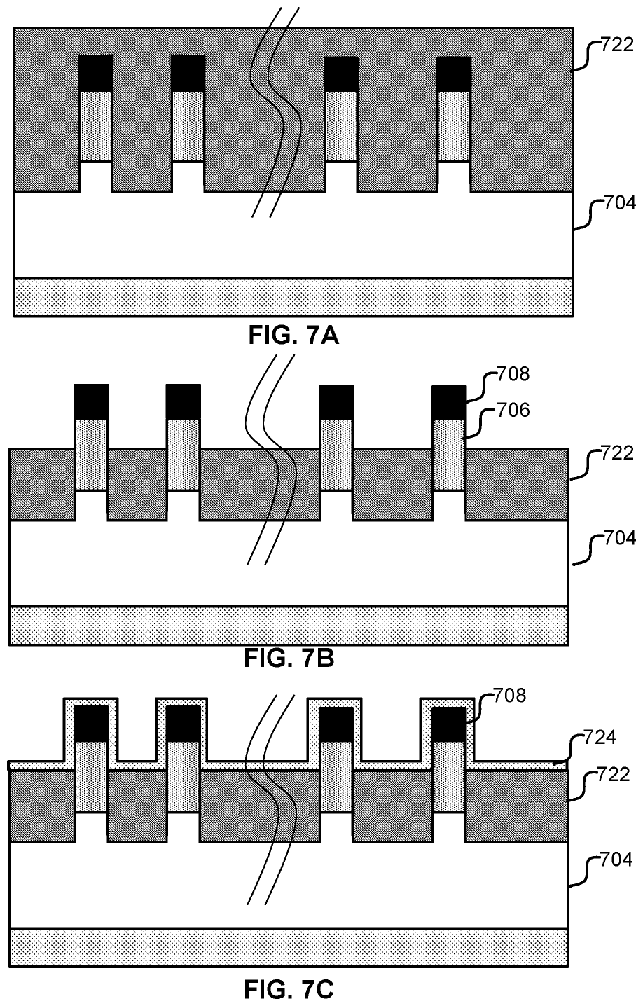

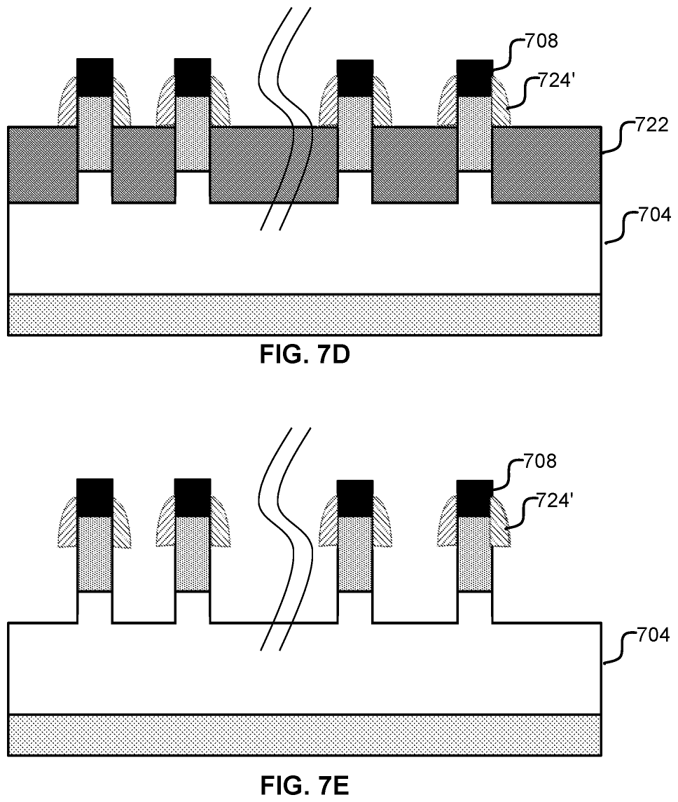

FIGS. 7A-7E are cross-sectional diagrams illustrating stages of forming a conformal layer on fins of a vertical FET according to some embodiments of the present disclosure. The stages may be performed after the stages illustrated in FIGS. 1A-1E.

Referring to FIG. 7A, a sacrificial coating layer 722 can be applied to the surfaces of the fins, trenches, and the patterned hard mask 708. The sacrificial coating layer 722 can be thicker than the height of the patterned hard mask 708, and can form a substantially planar surface above the fins. In some embodiments, the sacrificial coating layer 722 is a spin-on glass. In some embodiments, the sacrificial coating layer 722 is a deposited dielectric, such as silicon dioxide. In some embodiments, the dielectric is deposited by PECVD. In some embodiments, the top surface of sacrificial coating layer 722 is 1-2 μm above the top surface of the patterned hard mask 708.

Referring to FIG. 7B, the sacrificial coating layer 722 can be etched back to expose the patterned hard mask 708 and a portion of the sidewalls of the fins formed in second III-nitride layer 706. The extent of the exposed portion of the sidewalls may be controlled by controlling the extent of the etchback (e.g., by controlling the time of the etch). In some embodiments, the etch process is performed using a plasma containing fluorine.

Referring to FIG. 7C, a dielectric layer 724 can be deposited on the patterned hard mask 708, the exposed portion of the sidewalls of the fins, and the sacrificial coating layer 722. In some embodiments, the dielectric layer 724 is one of silicon nitride, silicon-aluminum nitride, or aluminum nitride. In an embodiment, the dielectric layer 724 is approximately 100 nm thick. In some embodiments, the dielectric layer 724 is deposited by one of PECVD, LPCVD or ALD.

Referring to FIG. 7D, a directional etch can be used to remove the dielectric layer 724 from the top surface of the patterned hard mask 708 and the top surface of the sacrificial coating layer 722. A dielectric spacer is left on the sidewall of the patterned hard mask 708 and a portion of the sidewalls of the fins. In an embodiment, the directional etch is performed using an RIE process. In an embodiment, the directional etch uses a fluorine-containing plasma. In an embodiment, the directional etch uses a chlorine-containing plasma. In another embodiment, the directional etch uses a fluorine-containing plasma.

Referring to FIG. 7E, the sacrificial coating layer 722 is removed to expose a lower portion of the sidewalls of the fins, the trenches, and the top surface of the first III-nitride layer 704 at the bottom of the trenches. In an embodiment, the sacrificial coating layer 722 is removed using a wet etch process.

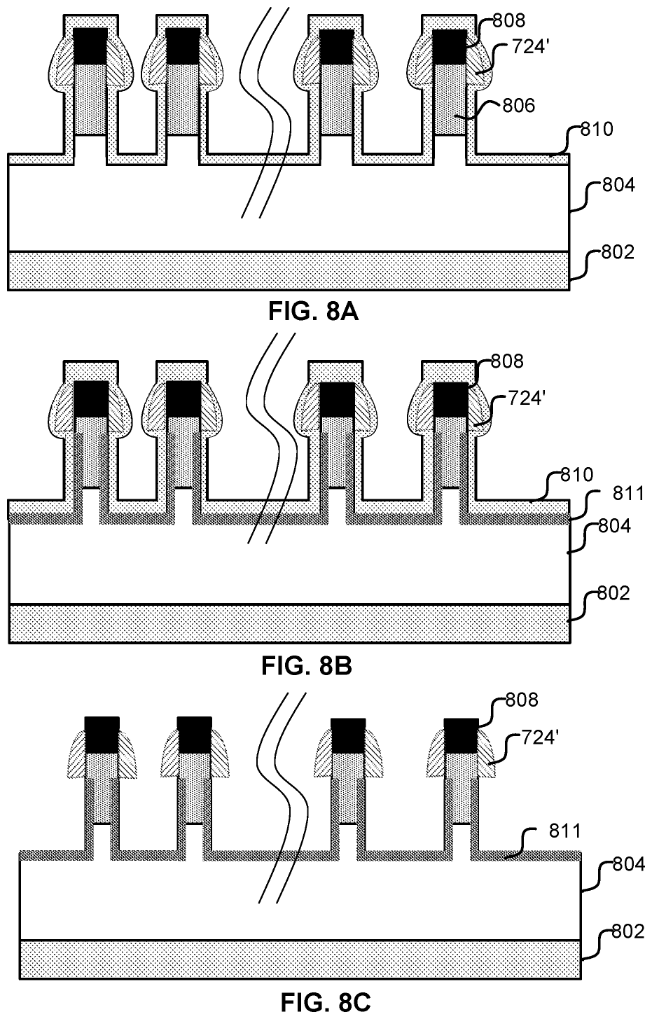

FIGS. 8A-8C are cross-sectional diagrams illustrating stages of fabricating a diffused-gate vertical FET by solid-phase diffusion according to some embodiments of the present disclosure. The stages may be performed subsequent to the stages illustrated in FIGS. 7A-7E.

Referring to FIG. 8A, a dopant diffusion layer 810 can be formed on the exposed surfaces of the fins, the trenches, and the patterned hard mask 808. In some embodiments, the dopant diffusion layer 810 is conformal to the exposed surfaces. In some embodiments, the dopant diffusion layer 810 may be a metallic material such as magnesium, zinc, combinations thereof, or the like. In some embodiments, the dopant diffusion layer 810 may be a metallic oxide material such as magnesium oxide, zinc oxide, combinations thereof, or the like. In some embodiments, the dopant diffusion layer 810 further includes a dielectric material such as silicon nitride, silicon dioxide, silicon-aluminum nitride, or the like, disposed on the metallic or metallic oxide material. The material layers may be deposited by LPCVD, PECVD, physical vapor deposition (PVD), ALD or the like. In some embodiments, the metallic or metallic-oxide material has a thickness between 50 and 100 nm. In some embodiments, the dielectric material has a thickness between 50 and 150 nm.

Referring to FIG. 8B, a thermal diffusion process can be performed to diffuse the p-type dopants into the exposed surfaces of the first III-nitride layer 804 and the second III-nitride layer 806 to form a diffused p-GaN gate layer. The first III-nitride layer 804 can be coupled to a III-nitride substrate 802. In some embodiments, the thermal treatment may be performed in a furnace at temperatures from 900° C. to 1100° C. In some embodiments, the thermal treatment may be performed in a rapid thermal annealer at temperatures from 1000° C. to 1450° C. In some embodiments the thermal treatment may be performed at a high ambient pressure (e.g., at 1 GPa in a N₂ ambient). In some embodiments the heating may be a result of a series of rapid pulses (e.g., microwave). In some embodiments, the diffused p-GaN gate layer has a junction depth between 25 and 50 nm. In some embodiments, the diffused p-GaN gate layer has a junction depth between 50 and 100 nm. In an embodiment, the dopant metallurgical concentration at the interface between the diffusion dopant material and the III-nitride semiconductor layers is 1-3×10¹⁹ atoms/cm³.

Referring to FIG. 8C, the dopant diffusion layer 810 can be removed to expose the gate region 811, e.g., the diffused p-GaN gate layer, on the surfaces of the fins and the trenches. In some embodiments, the dopant diffusion layer 810 is removed by a wet etch process. This results in a similar structure to that shown in FIG. 5D using an etchback of the diffusion dopant material 510. However, a dielectric spacer 724′ remains above the gate region 811. The dielectric spacer 724′ can act as a spacer structure to prevent the device from shorting.

The stages illustrated in of FIGS. 5F-5J may be performed subsequent to the stage illustrated in FIG. 8C. As a result, the structure illustrated in FIG. 5J can be produced, either using the process flow utilizing a diffusion dopant layer in conjunction with a sacrificial planarization material 520 illustrated in relation to FIGS. 5A-5J or a dielectric spacer 724′ illustrated in relation to FIGS. 8A-8C.

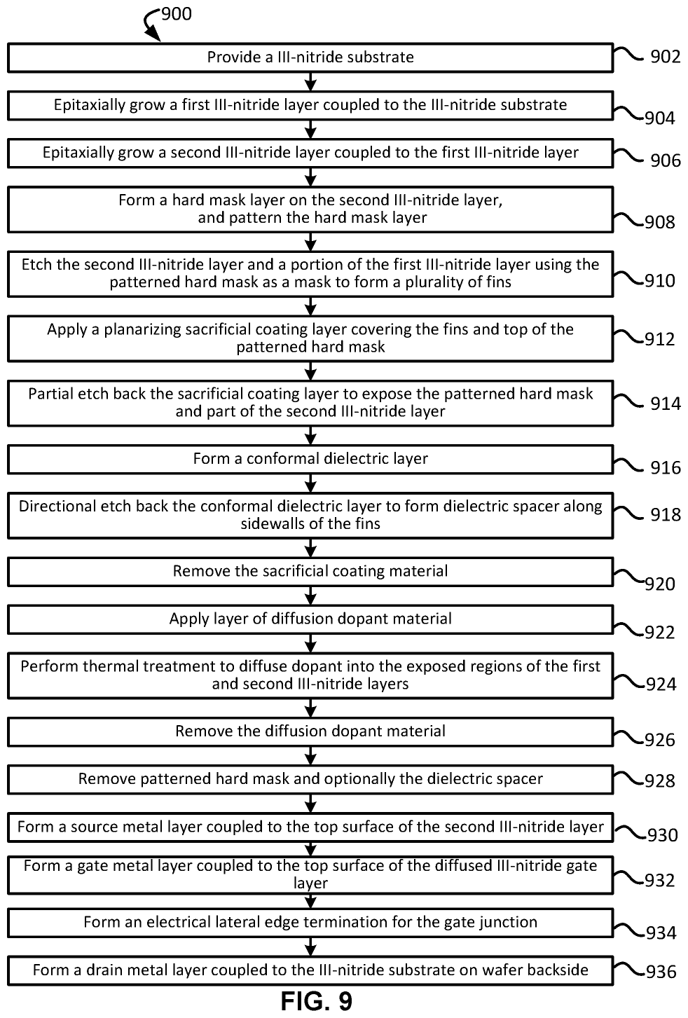

FIG. 9 is a flowchart illustrating a method for fabricating a diffused-gate vertical FET by solid-phase diffusion according to some embodiments of the present disclosure. A III-nitride substrate is provided (902). In an embodiment, the III-nitride substrate is an N+ GaN substrate having a resistivity in a range of about 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Method 900 also includes forming a first III-nitride epitaxial layer, for example, a 5-12 μm thick first III-nitride epitaxial layer (e.g., an N− GaN epitaxial layer deposited on the III-nitride substrate (904). The first III-nitride epitaxial layer is epitaxially grown on the III-nitride substrate at a temperature between 950 and 1100° C. and is characterized by a first dopant concentration, e.g., N-type doping with a dopant concentration of about 1×10¹⁶ atoms/cm³. In some embodiments, the first III-nitride epitaxial layer is a drift layer including a uniformly doped region (layer) on the III-nitride substrate and a graded doping region (layer) on the uniformly doped region. In an embodiment, the uniformly doped region has a thickness of about 10.5 μm, and the graded doping region has a thickness of about 0.3 μm. In an embodiment, the surface of substrate is miscut from the c-plane at an angle to facilitate high-quality epitaxial growth for high-voltage operation of the drift layer.

Method 900 further includes forming a second III-nitride epitaxial layer on the first III-nitride epitaxial layer (906). In an embodiment, the second III-nitride epitaxial layer is epitaxially grown on the first III-nitride epitaxial layer with a thickness of about 0.7-0.9 μm and is characterized by a second dopant concentration, e.g., N-type doping. The second dopant concentration is higher than the first dopant concentration in some embodiments. In an embodiment, the second dopant concentration is about 1.3×10¹⁷ atoms/cm³. In an embodiment, the second III-nitride epitaxial layer has a more highly doped surface layer, e.g., about 1-3×10¹⁸ atoms/cm³, with a thickness of 30-100 nm.

Method 900 further includes forming and patterning a hard mask layer on the second III-nitride epitaxial layer (908). In some embodiments, the hard mask layer may be a dielectric material such as silicon nitride, silicon dioxide, silicon oxynitride, silicon-aluminum nitride or the like. The dielectric material may be deposited by LPCVD, PECVD, ALD or the like. In some embodiments, the hard mask layer is a composite hard mask including a metal layer on the second III-nitride epitaxial layer and a dielectric hard mask layer on the metal layer. In some embodiments, the metal layer is a refractory metal, refractory metal alloy, or refractory metal nitride (e.g., TiN). The hard mask layer may be patterned using photolithography in combination with an RIE process. In some embodiments with a composite hard mask, the dielectric hard mask layer is first patterned, and then the patterned dielectric hard mask is used as a hard mask to pattern the metal layer.

Method 900 further includes forming a recess region in the second III-nitride epitaxial layer using the patterned hard mask by an etch process, e.g., an RIE process (910), to form fins separated by trenches. In an embodiment, the etched recess extends into the first III-nitride epitaxial layer. In an embodiment, the etched recess extends partially (e.g., 0.1 μm) into the graded layer at the top of the first III-nitride epitaxial layer.

Method 900 further includes applying a sacrificial coating layer to the surfaces of the fins and the patterned hard mask (912) to create a substantially planar surface. In some embodiments, the sacrificial coating layer is a spin-on glass. In some embodiments, the sacrificial coating layer is silicon dioxide. In some embodiments, the sacrificial coating layer is deposited using PECVD. In some embodiments, the top surface of the sacrificial coating layer is 1-2 μm above the top surface of the patterned hard mask.

Method 900 further includes etching back the sacrificial coating layer to expose the patterned hard mask and a portion of the sidewalls of the fins (914). In some embodiments, the etch is performed using a fluorine-containing plasma.

Method 900 further includes depositing a conformal dielectric layer on the exposed surfaces of the patterned hard mask, the fin sidewalls, and the sacrificial coating layer (916). In some embodiments, the conformal dielectric layer is one of silicon nitride, silicon-aluminum nitride, or aluminum nitride. In some embodiments, the conformal dielectric layer is deposited by one of PECVD, LPCVD, or ALD.

Method 900 further includes performing a directional (anisotropic) etch of the conformal dielectric layer (918) to leave a “spacer” layer on the sidewalls of the patterned hard mask and a portion of the fin sidewalls. In some embodiments, the directional etch is performed using an RIE process.

Method 900 further includes removal of the sacrificial coating layer (920) to expose the remaining portions of the fin sidewalls and the trench bottom regions. In some embodiments, the sacrificial coating layer is removed using a wet etch.

Method 900 further includes applying a layer of a diffusion dopant material to the surfaces of the fins and the patterned hard mask (922). In some embodiments, the layer of diffusion dopant material may include either a metal layer formed with a p-type dopant (e.g., Mg, Zn, combinations thereof, and the like) or a metallic oxide layer formed with a p-type dopant (e.g., MgO, ZnO, combinations thereof, and the like), in contact with the exposed III-nitride surfaces of the fins. In some embodiments, the thickness of the metal or metallic oxide layer is 50-100 nm. In some embodiments, the layer of diffusion dopant material may further include a second layer of dielectric material (e.g., SiO₂, Si₃N₄ or the like) disposed on the metal or metallic oxide layer.

Method 900 further includes performing a thermal treatment to diffuse the p-type dopant into the exposed surfaces of the first and second III-nitride semiconductor layers (924). In some embodiments, the thermal treatment may be performed in a furnace at temperatures from 900° C. to 1100° C. In some embodiments, the thermal treatment may be performed in a rapid thermal annealer at temperatures from 1000° C. to 1450° C. In some embodiments the thermal treatment may be performed at a high ambient pressure (e.g., at 1 GPa in a N₂ ambient). In some embodiments the heating may be a result of a series of rapid pulses (e.g. microwave).

Method 900 further includes removal of the diffusion dopant material (926). In some embodiments, the removal is performed using a wet etch.

Method 900 further includes removing the patterned hard mask on the top surface of the second III-nitride layer (928). Optionally, the spacer may also be removed. In some embodiments where a composite hard mask layer is used, the top dielectric layer may be removed, leaving the metal layer.

Method 900 further includes forming a source contact structure on the top surface of the second III-nitride layer (930). In some embodiments, the metal hard mask layer is left in place, and the source contact structure is formed on top of the metal hard mask layer. In some embodiments, the source contact structure is formed using titanium and aluminum.

Method 900 further includes forming a forming a gate contact structure on that exposed surface portion of the diffused gate layer overlaying the top surface of the first III-nitride epitaxial layer (932). The gate contact structure may include nickel, gold, palladium, platinum, molybdenum, and the like.

Method 900 further includes forming a junction-terminated edge (“edge termination”) for the p-GaN layer at the lateral edges of the device active region (934). In some cases, the p-GaN layer is connected to the gate, in others to the source. In some embodiments, this edge termination is formed using a tapered junction.

Method 900 further includes forming a drain contact at the bottom side of the substrate by forming a metallic contact to the bottom side of substrate (936).

It should be appreciated that the specific steps illustrated in FIG. 9 provide a particular method of fabricating a vertical FET device with a diffused gate layer according to an embodiment of the present invention. Other sequences of steps may also be performed according to alternative embodiments. For example, alternative embodiments of the present invention may perform the steps outlined above in a different order. Moreover, the individual steps illustrated in FIG. 9 may include multiple sub-steps that may be performed in various sequences as appropriate to the individual step. Furthermore, additional steps may be added or removed depending on the particular application. One of ordinary skill in the art would recognize many variations, modifications, and alternatives.

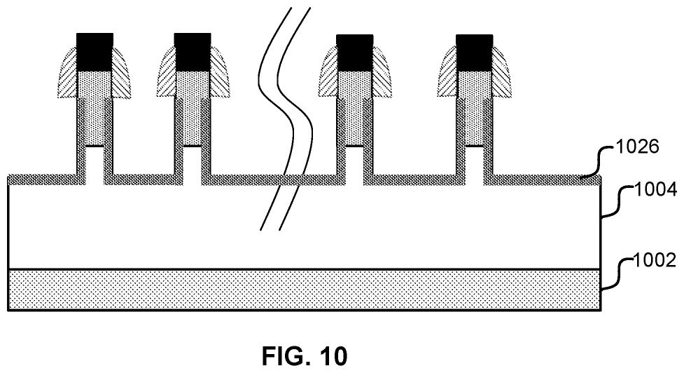

FIG. 10 is a cross-sectional diagram illustrating fabrication of a diffused-gate vertical FET by gas-phase diffusion according to some embodiments of the present disclosure. The stage may be performed subsequent to the stages illustrated in FIGS. 7A-7E.

Referring to FIG. 10, the structure of the III-nitride substrate 1002 and the first III-nitride layer 1004 can be exposed to an ambient containing a gaseous p-type dopant precursor to form a doped p-GaN gate layer 1026 using diffusion. In some embodiments, the p-type dopant precursor gas is e.g., bis-cyclo-penta-dienyl-magnesium in an ammonia-rich ambient in a metallorganic chemical vapor deposition (MOCVD) reactor, at temperatures between 950° C. and 1150° C. and pressures between 100 mTorr and 1 atmosphere. In some embodiments, the diffused junction depth is between 50 and 100 nm. In some embodiments, the peak concentration of the p-type dopant is between 5×10¹⁸ and 3×10¹⁹ atoms/cm³.

The stages illustrated in FIGS. 5F-5J may be performed subsequent to the stage illustrated in FIG. 10.

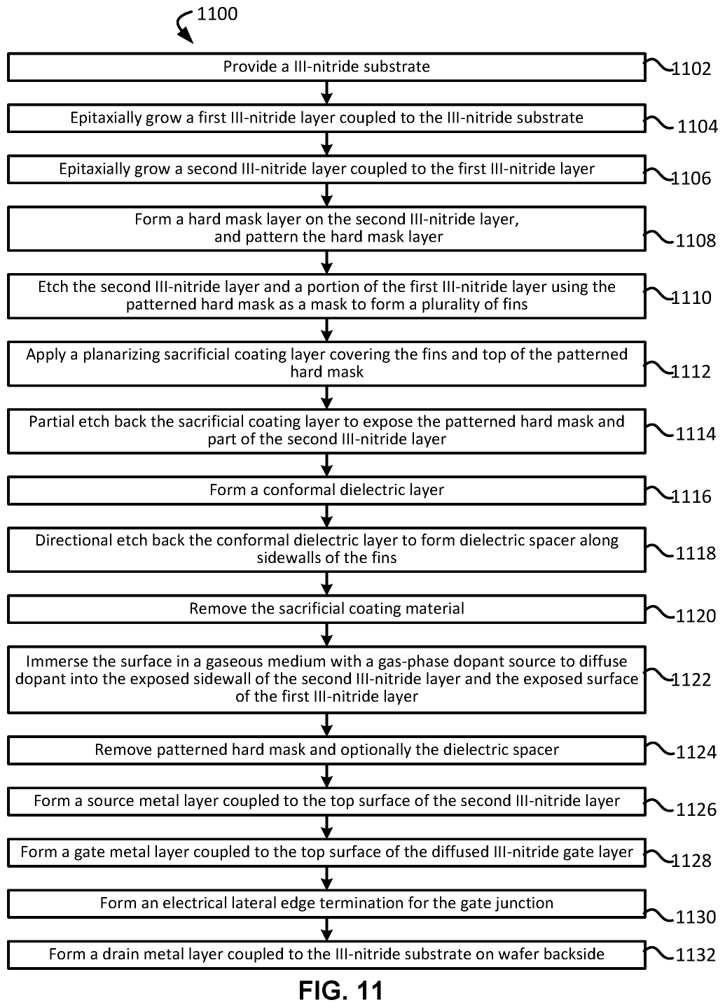

FIG. 11 is a flowchart illustrating a method for fabricating a diffused-gate vertical FET by gas-phase diffusion according to some embodiments of the present disclosure. A III-nitride substrate is provided (1102). In an embodiment, the III-nitride substrate is an N+ GaN substrate having a resistivity in a range of about 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Method 1100 also includes forming a first III-nitride epitaxial layer, for example, a 5-12 μm thick first III-nitride epitaxial layer (e.g., an N− GaN epitaxial layer deposited on the III-nitride substrate (1104). The first III-nitride epitaxial layer is epitaxially grown on the III-nitride substrate at a temperature between 950 and 1100° C. and is characterized by a first dopant concentration, e.g., N-type doping with a dopant concentration of about 1×10¹⁶ atoms/cm³. In some embodiments, the first III-nitride epitaxial layer is a drift layer including a uniformly doped region (layer) on the III-nitride substrate and a graded doping region (layer) on the uniformly doped region. In an embodiment, the uniformly doped region has a thickness of about 10.5 μm, and the graded doping region has a thickness of about 0.3 μm. In an embodiment, the surface of substrate is miscut from the c-plane at an angle to facilitate high-quality epitaxial growth for high-voltage operation of the drift layer.

Method 1100 further includes forming a second III-nitride epitaxial layer on the first III-nitride epitaxial layer (1106). In an embodiment, the second III-nitride epitaxial layer is epitaxially grown on the first III-nitride epitaxial layer with a thickness of about 0.7-0.9 μm and is characterized by a second dopant concentration, e.g., N-type doping. The second dopant concentration is higher than the first dopant concentration in some embodiments. In an embodiment, the second dopant concentration is about 1.3×10¹⁷ atoms/cm³. In an embodiment, the second III-nitride epitaxial layer has a more highly doped surface layer, e.g., about 1-3×10¹⁸ atoms/cm³, with a thickness of 30-100 nm.

Method 1100 further includes forming and patterning a hard mask layer on the second III-nitride epitaxial layer (1108). In some embodiments, the hard mask layer may be a dielectric material such as silicon nitride, silicon dioxide, silicon oxynitride, silicon-aluminum nitride or the like. The dielectric material may be deposited by LPCVD, PECVD, ALD or the like. In some embodiments, the hard mask layer is a composite hard mask including a metal layer on the second III-nitride epitaxial layer and a dielectric hard mask layer on the metal layer. In some embodiments, the metal layer is a refractory metal, refractory metal alloy, or refractory metal nitride (e.g., TiN). The hard mask layer may be patterned using photolithography in combination with an RIE process. In some embodiments with a composite hard mask, the dielectric hard mask layer is first patterned, and then the patterned dielectric hard mask is used as a hard mask to pattern the metal layer.

Method 1100 further includes forming a recess region in the second III-nitride epitaxial layer using the patterned hard mask by an etch process, e.g., an RIE process (1110), to form fins separated by trenches. In an embodiment, the etched recess extends into the first III-nitride epitaxial layer. In an embodiment, the etched recess extends partially (e.g., 0.1 μm) into the graded layer at the top of the first III-nitride epitaxial layer.

Method 1100 further includes applying a sacrificial coating layer to the surfaces of the fins and the patterned hard mask (1112) to create a substantially planar surface. In some embodiments, the sacrificial coating layer is a spin-on glass. In some embodiments, the sacrificial coating layer is silicon dioxide. In some embodiments, the sacrificial coating layer is deposited using PECVD. In some embodiments, the top surface of the sacrificial coating layer is 1-2 μm above the top surface of the patterned hard mask.

Method 1100 further includes etching back the sacrificial coating layer to expose the patterned hard mask and a portion of the sidewalls of the fins (1114). In some embodiments, the etch is performed using a fluorine-containing plasma.

Method 1100 further includes depositing a conformal dielectric layer on the exposed surfaces of the patterned hard mask, the fin sidewalls, and the sacrificial coating layer (1116). In some embodiments, the conformal dielectric layer is one of silicon nitride, silicon-aluminum nitride, or aluminum nitride. In some embodiments, the conformal dielectric layer is deposited by one of PECVD, LPCVD, or ALD.

Method 1100 further includes performing a directional (anisotropic) etch of the conformal dielectric layer (1118) to leave a “spacer” layer on the sidewalls of the patterned hard mask and a portion of the fin sidewalls. In some embodiments, the directional etch is performed using an RIE process.

Method 1100 further includes removal of the sacrificial coating layer (1120) to expose the remaining portions of the fin sidewalls and the trench bottom regions. In some embodiments, the sacrificial coating layer is removed using a wet etch.

Method 1100 further includes exposing the structure to an ambient containing a gaseous p-type dopant precursor to form a doped p-GaN gate layer using diffusion (1122). In some embodiments, the p-type dopant precursor gas is e.g., bis-cyclo-penta-dienyl-magnesium in an ammonia-rich ambient in a MOCVD reactor, at temperatures between 950° C. and 1150° C. and pressures between 100 mTorr and 1 atmosphere. In some embodiments, the diffused junction depth is between 50 and 100 nm. In some embodiments, the peak concentration of the p-type dopant is between 5×10¹⁸ and 3×10¹⁹ atoms/cm³.

Method 1100 further includes removing the patterned hard mask on the top surface of the second III-nitride layer (1124). Optionally, the dielectric spacer may also be removed. In some embodiments where a composite hard mask layer is used, the top dielectric layer may be removed, leaving the metal layer.

Method 1100 further includes forming a source contact structure on the top surface of the second III-nitride layer (1126). In some embodiments, the metal hard mask layer is left in place, and the source contact structure is formed on top of the metal hard mask layer. In some embodiments, the source contact structure is formed using titanium and aluminum.

Method 1100 further includes forming a forming a gate contact structure on that exposed surface portion of the diffused gate layer overlaying the top surface of the first III-nitride epitaxial layer (1128). The gate contact structure may include nickel, gold, palladium, platinum, molybdenum, and the like.

Method 1100 further includes forming a junction-terminated edge (“edge termination”) for the p-GaN layer at the lateral edges of the device active region (1130). In some cases, the p-GaN layer is connected to the gate, in others to the source. In some embodiments, this edge termination is formed using a tapered junction.

Method 1100 further includes forming a drain contact at the bottom side of the substrate by forming a metallic contact to the bottom side of substrate (1132).

It should be appreciated that the specific steps illustrated in FIG. 11 provide a particular method of fabricating a vertical FET device with a diffused gate layer according to an embodiment of the present invention. Other sequences of steps may also be performed according to alternative embodiments. For example, alternative embodiments of the present invention may perform the steps outlined above in a different order. Moreover, the individual steps illustrated in FIG. 11 may include multiple sub-steps that may be performed in various sequences as appropriate to the individual step. Furthermore, additional steps may be added or removed depending on the particular application. One of ordinary skill in the art would recognize many variations, modifications, and alternatives.

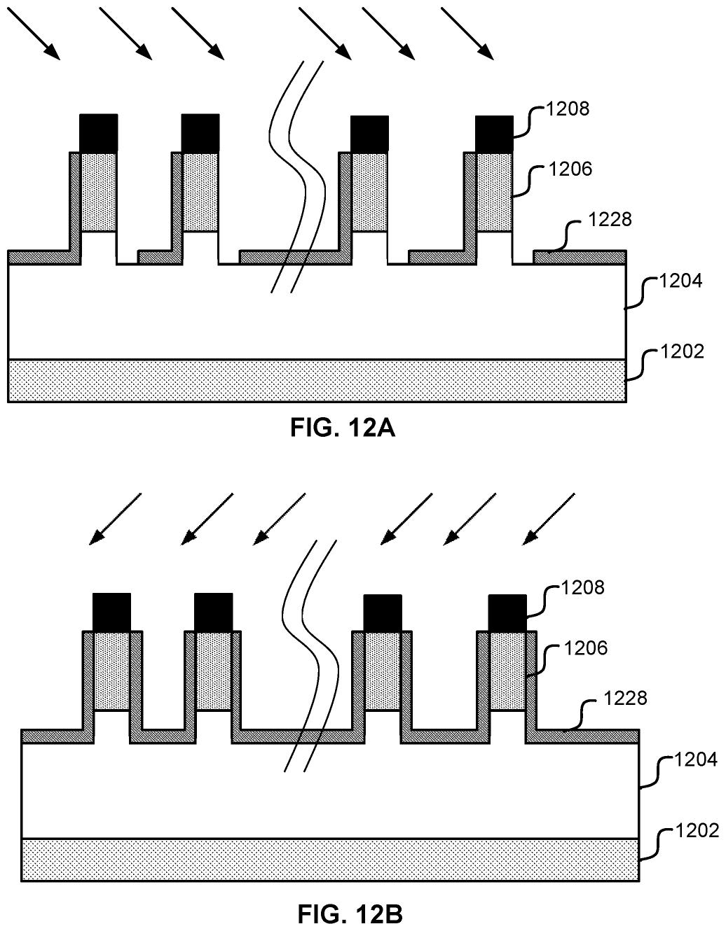

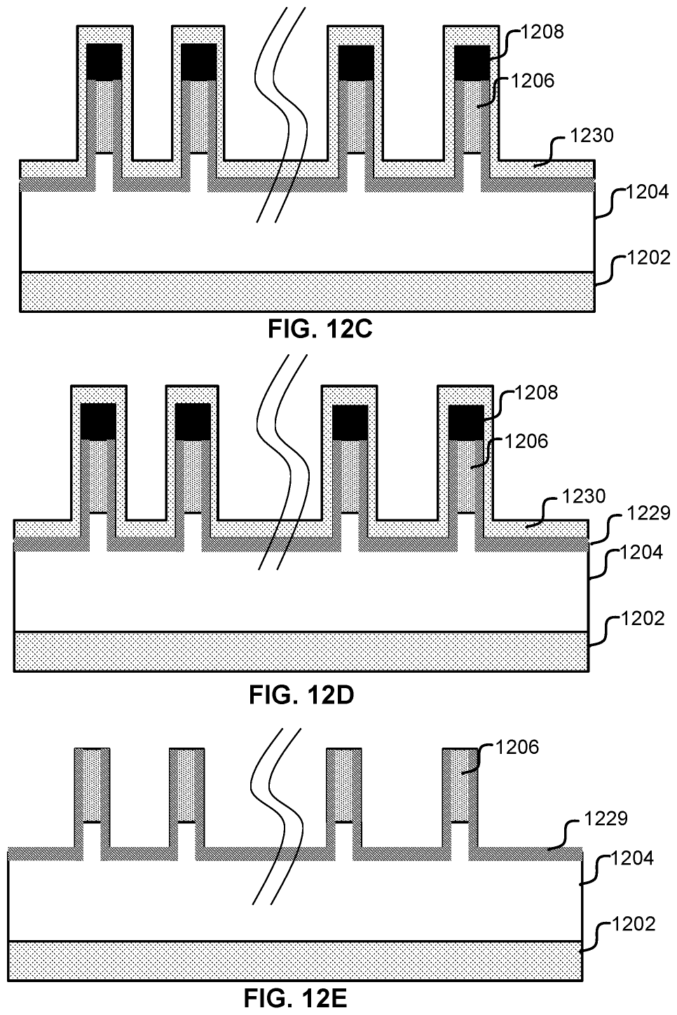

FIGS. 12A-12E are cross-sectional diagrams illustrating an example of fabricating an implanted-gate vertical FET according to some embodiments of the present disclosure. These stages may be performed subsequent to the stages illustrated in FIGS. 1A-1E.

In FIGS. 12A-B, p-type dopant atoms 1228 can be ion-implanted into the exposed surfaces of the first III-nitride layer 1204 and the second III-nitride layer 1206 in the fins. The first III-nitride layer 1204 can be coupled to a III-nitride substrate 1202. In some embodiments, the implantation is performed at multiple angles with respect to the normal to the horizontal surface of the bottoms of the trenches to implant the different sidewall regions of the trench. The implant angle can affect the depth of the p-type dopant atoms 1228 in the first III-nitride layer 1204 and the second III-nitride layer 1206. In some embodiments, the p-type dopant atoms 1228 include Mg, Be, Zn or Ca. In some embodiments, the p-type dopant atoms 1228 are implanted to a depth of 50-100 nm in the fin sidewalls. In some embodiments, the peak concentration of the implanted p-type dopant atoms 1228 is between 1×10¹⁸ and 3×10¹⁹ atoms/cm³.

Referring to FIG. 12C, a protective layer 1230 can be deposited on the exposed surfaces of the fins, the trenches, and on the patterned hard mask 1208. The protective layer 1230 can prevent GaN from decomposing into a gallium rich surface at temperatures above 1000° C. In some embodiments, the protective layer 1230 is a dielectric material such as silicon nitride, silicon dioxide, silicon-aluminum nitride, or the like. The protective layer 1230 may be deposited by LPCVD, PECVD, MOCVD, PVD, ALD, or the like. In some embodiments, the protective layer 1230 has a thickness between 50 and 150 nm. In some embodiments, the protective layer 1230 is conformal to surfaces of the trench, the fins, and patterned hard mask 1208.

Referring to FIG. 12D, a thermal diffusion process is performed to activate the implanted p-type dopant atoms 1228 to form a gate region 1229, e.g., a p-GaN gate region. In some embodiments, the thermal treatment may be performed in a furnace at temperatures from 1000° C. to 1200° C. In some embodiments, the thermal treatment may be performed in a rapid thermal annealer at temperatures from 1000° C. to 1450° C. In some embodiments the thermal treatment may be performed at a high ambient pressure (e.g., at 1 GPa in a N₂ ambient), with or without the protective layer. In some embodiments the heating may be a result of a series of rapid pulses (e.g. microwave).

Referring to FIG. 12E, the protective layer 1230 can be removed to expose the gate region 1229 on the surfaces of the fins and the trenches. In some embodiments, the protective layer 1230 is removed by a wet etch process.

The stages illustrated in FIG. 3A-3D may be performed subsequent to FIG. 12E to complete the implanted-gate vertical FET.

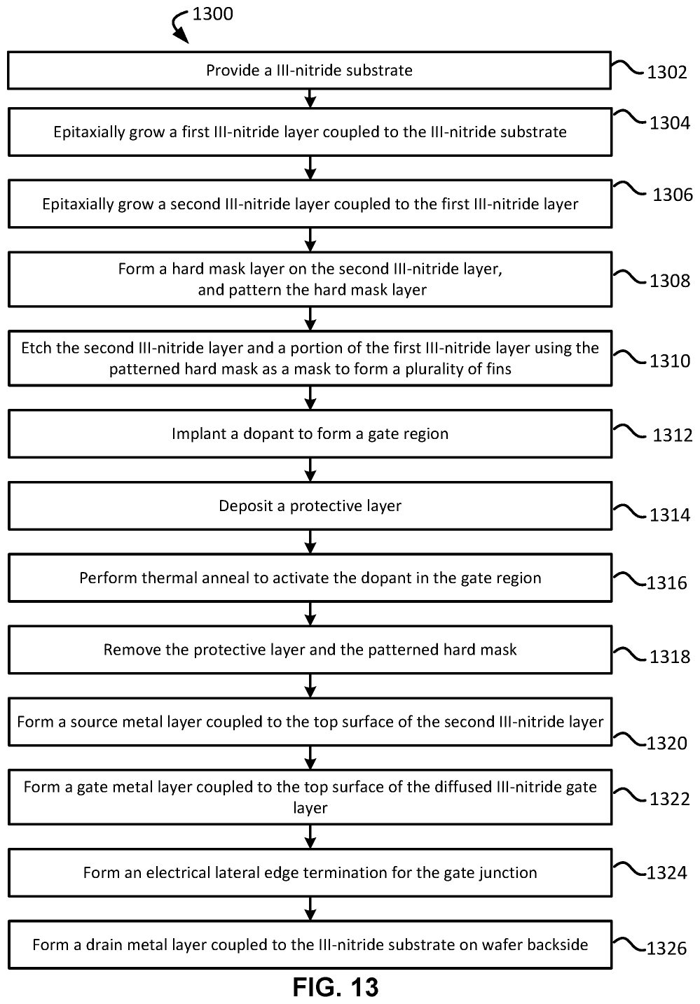

FIG. 13 is a flowchart illustrating a method for fabricating an implanted-gate vertical FET according to some embodiments of the present disclosure. A III-nitride substrate is provided (1302). In an embodiment, the III-nitride substrate is an N+ GaN substrate having a resistivity in a range of about 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Method 1300 also includes forming a first III-nitride epitaxial layer, for example, a 5-12 μm thick first III-nitride epitaxial layer (e.g., an N− GaN epitaxial layer deposited on the III-nitride substrate (1304). The first III-nitride epitaxial layer is epitaxially grown on the III-nitride substrate at a temperature between 950 and 1100° C. and is characterized by a first dopant concentration, e.g., N-type doping with a dopant concentration of about 1×10¹⁶ atoms/cm³. In some embodiments, the first III-nitride epitaxial layer is a drift layer including a uniformly doped region (layer) on the III-nitride substrate and a graded doping region (layer) on the uniformly doped region. In an embodiment, the uniformly doped region has a thickness of about 10.5 μm, and the graded doping region has a thickness of about 0.3 μm. In an embodiment, the surface of substrate is miscut from the c-plane at an angle to facilitate high-quality epitaxial growth for high-voltage operation of the drift layer.

Method 1300 further includes forming a second III-nitride epitaxial layer on the first III-nitride epitaxial layer (1306). In an embodiment, the second III-nitride epitaxial layer is epitaxially grown on the first III-nitride epitaxial layer with a thickness of about 0.7-0.9 μm and is characterized by a second dopant concentration, e.g., N-type doping. The second dopant concentration is higher than the first dopant concentration in some embodiments. In an embodiment, the second dopant concentration is about 1.3×10¹⁷ atoms/cm³. In an embodiment, the second III-nitride epitaxial layer has a more highly doped surface layer, e.g., about 1-3×10¹⁸ atoms/cm³, with a thickness of 30-100 nm.

Method 1300 further includes forming and patterning a hard mask layer on the second III-nitride epitaxial layer (1308). In some embodiments, the hard mask layer may be a dielectric material such as silicon nitride, silicon dioxide, silicon oxynitride, silicon-aluminum nitride or the like. The dielectric material may be deposited by LPCVD, PECVD, ALD, or the like. In some embodiments, the hard mask layer is a composite hard mask including a metal layer on the second III-nitride epitaxial layer and a dielectric hard mask layer on the metal layer. In some embodiments, the metal layer is a refractory metal, refractory metal alloy, or refractory metal nitride (e.g., TiN). The hard mask layer may be patterned using photolithography in combination with an RIE process. In some embodiments with a composite hard mask, the dielectric hard mask layer is first patterned, and then the patterned dielectric hard mask is used as a hard mask to pattern the metal layer.

Method 1300 further includes forming a recess region in the second III-nitride epitaxial layer using the patterned hard mask by an etch process, e.g., an RIE (process (1310), to form fins separated by trenches. In an embodiment, the etched recess extends into the first III-nitride epitaxial layer. In an embodiment, the etched recess extends partially (e.g., 0.1 μm) into the graded layer at the top of the first III-nitride epitaxial layer.

Method 1300 further includes implanting p-type dopant material into the surfaces of the fins (1312). In some embodiments, the implanted dopant is Mg, Zn, Be, Ca, combinations thereof, and the like. In some embodiments, the implantation is performed at multiple tilt angles to allow implantation into all exposed surfaces of the fin sidewall. In some embodiments, the dopant material is implanted to a depth of 50-100 nm.

Method 1300 further includes depositing a protective layer to encapsulate the implanted surface (1314). In some embodiments, the protective layer is a dielectric (e.g., silicon nitride, aluminum nitride, silicon-aluminum nitride, etc.). In some embodiments, the protective layer has a thickness between 50 and 100 nm.

Method 1300 further includes performing a thermal treatment to activate the implanted p-type dopant (1316). In some embodiments, the thermal treatment may be performed in a furnace at temperatures from 1000° C. to 1200° C. In some embodiments, the thermal treatment may be performed in a rapid thermal annealer at temperatures from 1000° C. to 1450° C. In some embodiments the thermal treatment may be performed at a high ambient pressure (e.g., at 1 GPa in a N₂ ambient), with or without the protective layer. In some embodiments the heating may be a result of a series of rapid pulses (e.g. microwave).

Method 1300 further includes removal of the protective layer (1318). In some embodiments, the removal is performed using a wet etch.

Method 1300 further includes forming a source contact structure on the top surface of the second III-nitride layer (1320). In some embodiments, the metal hard mask layer is left in place, and the source contact structure is formed on top of the metal hard mask layer. In some embodiments, the source contact structure is formed using titanium and aluminum.

Method 1300 further includes forming a forming a gate contact structure on that exposed surface portion of the implanted gate layer overlaying the top surface of the first III-nitride epitaxial layer (1322). The gate contact structure may include nickel, gold, palladium, platinum, molybdenum, and the like.

Method 1300 further includes forming a junction-terminated edge (“edge termination”) for the p-GaN layer at the lateral edges of the device active region (1324). In some cases, the p-GaN layer is connected to the gate, in others to the source. In some embodiments, this edge termination is formed using a tapered junction. In some embodiments, the implanted regions can be utilized to form the edge termination structure.

Method 1300 further includes forming a drain contact at the bottom side of the substrate by forming a metallic contact to the bottom side of substrate (1326).

It should be appreciated that the specific steps illustrated in FIG. 13 provide a particular method of fabricating a vertical FET device with an implanted gate layer according to an embodiment of the present invention. Other sequences of steps may also be performed according to alternative embodiments. For example, alternative embodiments of the present invention may perform the steps outlined above in a different order. Moreover, the individual steps illustrated in FIG. 13 may include multiple sub-steps that may be performed in various sequences as appropriate to the individual step. Furthermore, additional steps may be added or removed depending on the particular application. One of ordinary skill in the art would recognize many variations, modifications, and alternatives.

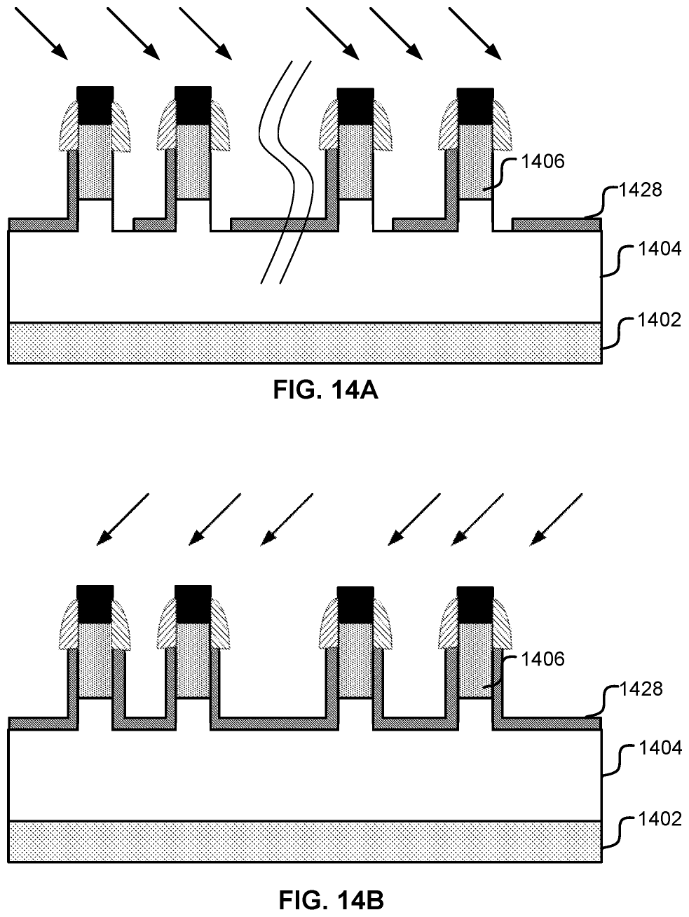

FIGS. 14A-14B are cross-sectional diagrams illustrating another example of fabricating an implanted-gate vertical FET according to some embodiments of the present disclosure. These stages may be performed subsequent to the stages illustrated in FIGS. 7A-7E.

In FIGS. 14A-14B, p-type dopant atoms 1428 can be ion-implanted into the exposed surfaces of the first III-nitride layer 1404 and the second III-nitride layer 1406 in the fins. The first III-nitride layer 1404 can be coupled to a III-nitride substrate 1402. In some embodiments, the implantation is performed at multiple angles with respect to the normal to the horizontal surface of the bottoms of the trenches to implant the different sidewall regions of the fins. In some embodiments, the p-type dopant atoms 1428 include Mg, Be, Zn or Ca. In some embodiments, the p-type dopant atoms 1428 are implanted to a depth of 50-100 nm in the fin sidewalls. In some embodiments, the peak concentration of the implanted p-type dopant atoms 1428 is between 1×10¹⁸ and 3×10¹⁹ atoms/cm³.

The stages illustrated in FIGS. 12C-12E and 3A-3D may be performed subsequent to the stages illustrated in FIGS. 14A-14B.

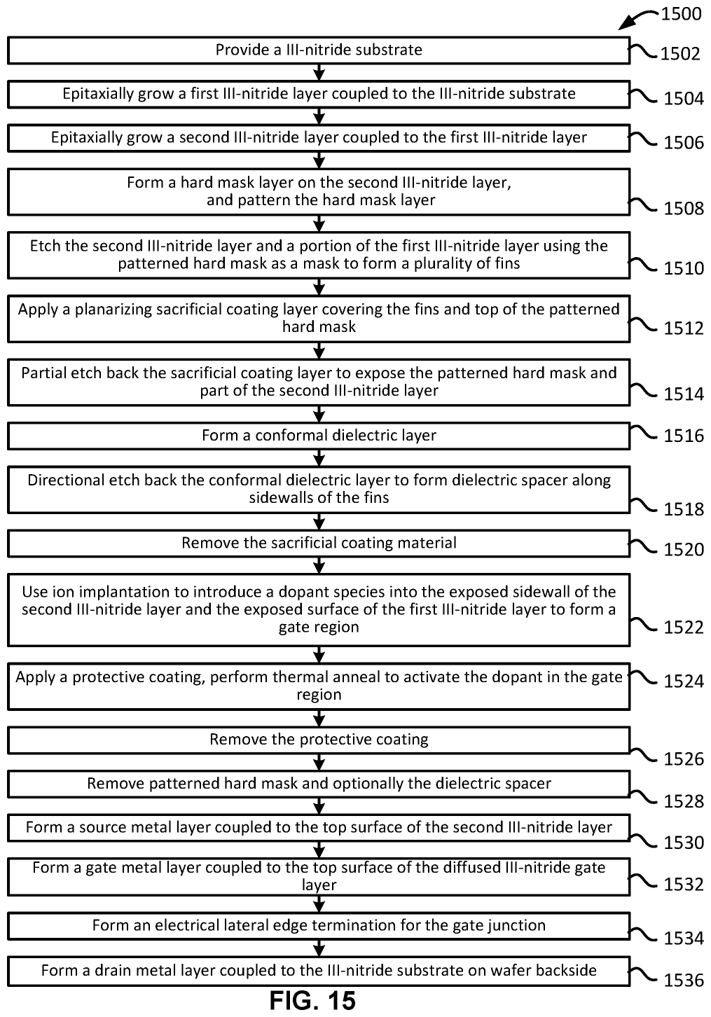

FIG. 15 is a flowchart illustrating another method for fabricating an implanted-gate vertical FET according to some embodiments of the present disclosure. A III-nitride substrate is provided (1502). In an embodiment, the III-nitride substrate is an N+ GaN substrate having a resistivity in a range of about 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Method 1500 also includes forming a first III-nitride epitaxial layer, for example, a 5-12 μm thick first III-nitride epitaxial layer (e.g., an N− GaN epitaxial layer deposited on the III-nitride substrate (1504). The first III-nitride epitaxial layer is epitaxially grown on the III-nitride substrate at a temperature between 950 and 1100° C. and is characterized by a first dopant concentration, e.g., N-type doping with a dopant concentration of about 1×10¹⁶ atoms/cm³. In some embodiments, the first III-nitride epitaxial layer is a drift layer including a uniformly doped region (layer) on the III-nitride substrate and a graded doping region (layer) on the uniformly doped region. In an embodiment, the uniformly doped region has a thickness of about 10.5 μm, and the graded doping region has a thickness of about 0.3 μm. In an embodiment, the surface of substrate is miscut from the c-plane at an angle to facilitate high-quality epitaxial growth for high-voltage operation of the drift layer.

Method 1500 further includes forming a second III-nitride epitaxial layer on the first III-nitride epitaxial layer (1506). In an embodiment, the second III-nitride epitaxial layer is epitaxially grown on the first III-nitride epitaxial layer with a thickness of about 0.7-0.9 μm and is characterized by a second dopant concentration, e.g., N-type doping. The second dopant concentration is higher than the first dopant concentration in some embodiments. In an embodiment, the second dopant concentration is about 1.3×10¹⁷ atoms/cm³. In an embodiment, the second III-nitride epitaxial layer has a more highly doped surface layer, e.g., about 1-3×10¹⁸ atoms/cm³, with a thickness of 30-100 nm.

Method 1500 further includes forming and patterning a hard mask layer on the second III-nitride epitaxial layer (1508). In some embodiments, the hard mask layer may be a dielectric material such as silicon nitride, silicon dioxide, silicon oxynitride, silicon-aluminum nitride or the like. The dielectric material may be deposited by LPCVD, PECVD, ALD or the like. In some embodiments, the hard mask layer is a composite hard mask including a metal layer on the second III-nitride epitaxial layer and a dielectric hard mask layer on the metal layer. In some embodiments, the metal layer is a refractory metal, refractory metal alloy, or refractory metal nitride (e.g., TiN). The hard mask layer may be patterned using photolithography in combination with an RIE process. In some embodiments with a composite hard mask, the dielectric hard mask layer is first patterned, and then the patterned dielectric hard mask is used as a hard mask to pattern the metal layer.

Method 1500 further includes forming a recess region in the second III-nitride epitaxial layer using the patterned hard mask by an etch process, e.g., an RIE process (1510), to form fins separated by trenches. In an embodiment, the etched recess extends into the first III-nitride epitaxial layer. In an embodiment, the etched recess extends partially (e.g., 0.1 μm) into the graded layer at the top of the first III-nitride epitaxial layer.

Method 1500 further includes applying a sacrificial coating layer to the surfaces of the fins and the patterned hard mask (1512) to create a substantially planar surface. In some embodiments, the sacrificial coating layer is a spin-on glass. In some embodiments, the sacrificial coating layer is silicon dioxide. In some embodiments, the sacrificial coating layer is deposited using PECVD. In some embodiments, the top surface of the sacrificial coating layer is 1-2 μm above the top surface of the patterned hard mask. In some embodiments, the sacrificial coating layer is omitted, and step 1514 is not performed.

Method 1500 further includes etching back the sacrificial coating layer to expose the patterned hard mask and a portion of the sidewalls of the fins (1514). In some embodiments, the etch is performed using a fluorine-containing plasma.

Method 1500 further includes depositing a conformal dielectric layer on the exposed surfaces of the patterned hard mask, of fin sidewalls, and the sacrificial coating layer (1516). In some embodiments, the conformal dielectric layer is one of silicon nitride, silicon-aluminum nitride, or aluminum nitride. In some embodiments, the conformal dielectric layer is deposited by one of PECVD, LPCVD, or ALD.

Method 1500 further includes performing a directional (anisotropic) etch of the conformal dielectric layer (1518) to leave a “spacer” layer on the sidewalls of the patterned hard mask and a portion of the fin sidewalls. In some embodiments, the directional etch is performed using an RIE process. In embodiments where the sacrificial coating layer is omitted, the spacer is present on the entire fin sidewall.

Method 1500 further includes removal of the sacrificial coating layer (1520) to expose the remaining portions of the fin sidewalls and the trench bottom regions. In some embodiments, the sacrificial coating layer is removed using a wet etch.

Method 1500 further includes implanting p-type dopant material into the surfaces of the fins (1522). In some embodiments, the implanted dopant is Mg, Zn, Be, Ca, combinations thereof, and the like. In some embodiments, the implantation is performed at multiple tilt angles to allow implantation into exposed surfaces of the fin sidewall. In some embodiments, the dopant material is implanted to a depth of 50-100 nm.

Method 1500 further includes depositing a protective layer to encapsulate the implanted surface, followed by a thermal treatment to activate the implanted p-type dopant material (1524). In some embodiments, the protective layer is a dielectric (e.g., silicon nitride, aluminum nitride, silicon-aluminum nitride, etc.). In some embodiments, the protective layer has a thickness between 50 and 100 nm. In some embodiments, the thermal treatment may be performed in a furnace at temperatures from 1000° C. to 1200° C. In some embodiments, the thermal treatment may be performed in a rapid thermal annealer at temperatures from 1000° C. to 1450° C. In some embodiments the thermal process may be performed at a high ambient pressure (e.g., at 1 GPa in a N₂ ambient), with or without the protective layer. In some embodiments the heating may be a result of a series of rapid pulses (e.g. microwave).

Method 1500 further includes removal of the protective layer (1526). In some embodiments, the removal is performed using a wet etch.

Method 1500 further includes removing the patterned hard mask on the top surface of the second III-nitride layer (1528). Optionally, the spacer may also be removed. In some embodiments where a composite hard mask layer is used, the top dielectric layer may be removed, leaving the metal layer.

Method 1500 further includes forming a source contact structure on the top surface of the second III-nitride layer (1530). In some embodiments, the metal hard mask layer is left in place, and the source contact structure is formed on top of the metal hard mask layer. In some embodiments, the source contact structure is formed using titanium and aluminum.

Method 1500 further includes forming a forming a gate contact structure on that exposed surface portion of the implanted gate layer overlaying the top surface of the first III-nitride epitaxial layer (1532). The gate contact structure may include nickel, gold, palladium, platinum, molybdenum, and the like.

Method 1500 further includes forming a junction-terminated edge (“edge termination”) for the p-GaN layer at the lateral edges of the device active region (1534). In some cases, the p-GaN layer is connected to the gate, in others to the source. In some embodiments, this edge termination is formed using a tapered junction.

Method 1500 further includes forming a drain contact at the bottom side of the substrate by forming a metallic contact to the bottom side of substrate (1536).

It should be appreciated that the specific steps illustrated in FIG. 15 provide a particular method of fabricating a vertical FET device with an implanted gate layer according to an embodiment of the present invention. Other sequences of steps may also be performed according to alternative embodiments. For example, alternative embodiments of the present invention may perform the steps outlined above in a different order. Moreover, the individual steps illustrated in FIG. 15 may include multiple sub-steps that may be performed in various sequences as appropriate to the individual step. Furthermore, additional steps may be added or removed depending on the particular application. One of ordinary skill in the art would recognize many variations, modifications, and alternatives.

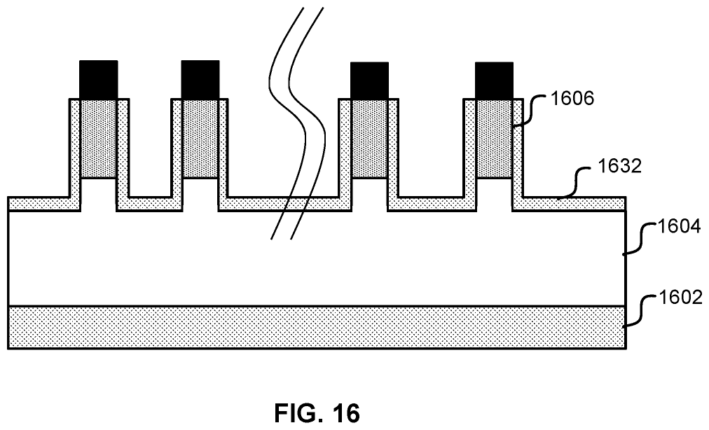

FIG. 16 is a cross-sectional diagram illustrating fabrication of a conformal epitaxial gate vertical FET according to some embodiments of the present disclosure. This may be performed subsequent to the stages illustrated in FIGS. 1A-1E.

Referring to FIG. 16, a selective area regrowth can be used to form a regrown epitaxial layer 1632, e.g., a conformal, p-doped III-nitride regrown epitaxial layer, on the exposed surfaces of the first III-nitride layer 1604 and the second III-nitride layer 1606 in the fins. The first III-nitride layer 1604 can be coupled to a III-nitride substrate 1602. In an embodiment, the regrowth is performed using MOCVD. In an embodiment, the p-type dopant is Mg. In an embodiment, the regrowth is performed in an NH₃ ambient. In an embodiment, the regrowth is performed at pressures between 50 mbar and 600 mbar. In an embodiment, the regrowth is performed at temperatures between 850° C. and 950° C. In some embodiments, the regrown epitaxial layer 1632 has a thickness on the sidewalls of the trench of between 50-150 nm. In some embodiments, the p-type dopant concentration is between 5×10¹⁸ and 3×10¹⁹ atoms/cm³.

The stages illustrated in FIGS. 12D and 12E followed by the stages illustrated in FIGS. 3A-3D may be performed subsequent to the stage illustrated in FIG. 16.

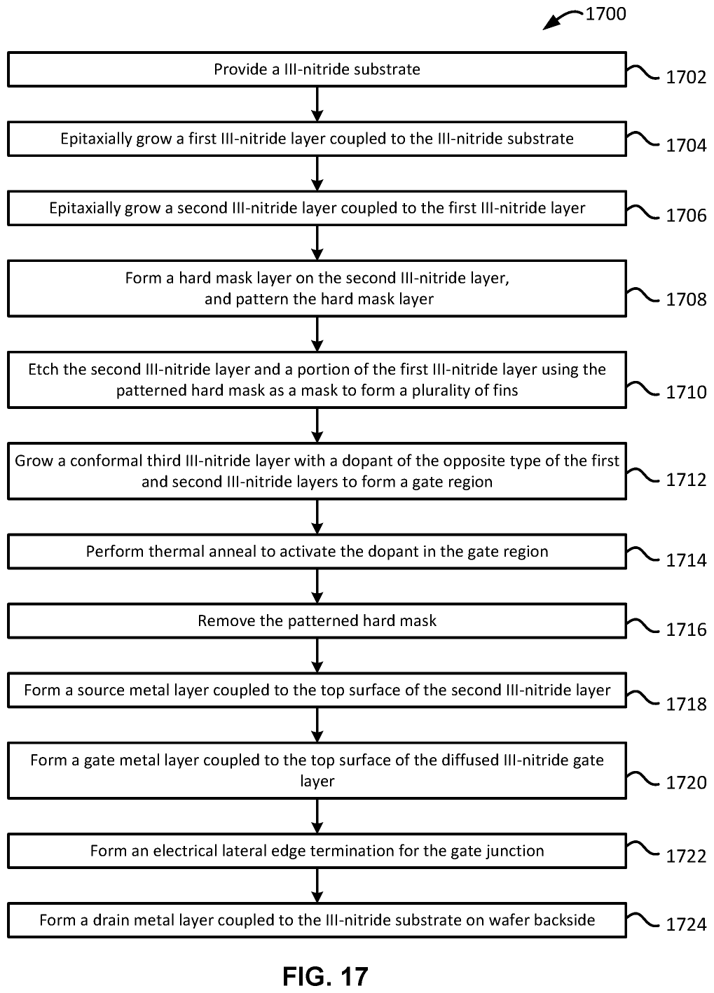

FIG. 17 is a flowchart illustrating a method for fabricating a conformal epitaxial gate vertical FET according to some embodiments of the present disclosure. A III-nitride substrate is provided (1702). In an embodiment, the III-nitride substrate is an N+ GaN substrate having a resistivity in a range of about 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Method 1700 also includes forming a first III-nitride epitaxial layer, for example, a 5-12 μm thick first III-nitride epitaxial layer (e.g., an N− GaN epitaxial layer deposited on the III-nitride substrate (1704). The first III-nitride epitaxial layer is epitaxially grown on the III-nitride substrate at a temperature between 950 and 1100° C. and is characterized by a first dopant concentration, e.g., N-type doping with a dopant concentration of about 1×10¹⁶ atoms/cm³. In some embodiments, the first III-nitride epitaxial layer is a drift layer including a uniformly doped region (layer) on the III-nitride substrate and a graded doping region (layer) on the uniformly doped region. In an embodiment, the uniformly doped region has a thickness of about 10.5 μm, and the graded doping region has a thickness of about 0.3 μm. In an embodiment, the surface of substrate is miscut from the c-plane at an angle to facilitate high-quality epitaxial growth for high-voltage operation of the drift layer.

Method 1700 further includes forming a second III-nitride epitaxial layer on the first III-nitride epitaxial layer (1706). In an embodiment, the second III-nitride epitaxial layer is epitaxially grown on the first III-nitride epitaxial layer with a thickness of about 0.7-0.9 μm and is characterized by a second dopant concentration, e.g., N-type doping. The second dopant concentration is higher than the first dopant concentration in some embodiments. In an embodiment, the second dopant concentration is about 1.3×10¹⁷ atoms/cm³. In an embodiment, the second III-nitride epitaxial layer has a more highly doped surface layer, e.g., about 1-3×10¹⁸ atoms/cm³, with a thickness of 30-100 nm.

Method 1700 further includes forming and patterning a hard mask layer on the second III-nitride epitaxial layer (1708). In some embodiments, the hard mask layer may be a dielectric material such as silicon nitride, silicon dioxide, silicon oxynitride, silicon-aluminum nitride or the like. The dielectric material may be deposited by LPCVD, PECVD, ALD or the like. In some embodiments, the hard mask layer is a composite hard mask including a metal layer on the second III-nitride epitaxial layer and a dielectric hard mask layer on the metal layer. In some embodiments, the metal layer is a refractory metal, refractory metal alloy, or refractory metal nitride (e.g., TiN). The hard mask layer may be patterned using photolithography in combination with an RIE process. In some embodiments with a composite hard mask, the dielectric hard mask layer is first patterned, and then the patterned dielectric hard mask is used as a hard mask to pattern the metal layer.

Method 1700 further includes forming a recess region in the second III-nitride epitaxial layer using the patterned hard mask by an etch process, e.g., an RIE process (1710). In an embodiment, the etched recess extends into the first III-nitride epitaxial layer. In an embodiment, the etched recess extends partially (e.g., 0.1 μm) into the graded layer at the top of the first III-nitride epitaxial layer.

Method 1700 further includes selective area regrowth of a conformal, p-doped III-nitride epitaxial layer on the exposed surfaces of the first and second semiconductor layers in the fins (1712). In an embodiment, the regrowth is performed using MOCVD. In an embodiment, the p-type dopant is Mg. In an embodiment, the regrowth is performed in an NH₃ ambient. In an embodiment, the regrowth is performed at pressures between 50 mbar and 600 mbar. In an embodiment, the regrowth is performed at temperatures between 850° C. and 950° C. In some embodiments, the regrown epitaxial layer has a thickness on the sidewalls of the trench of between 50-150 nm. In some embodiments, the p-type dopant concentration is between 5×10¹⁸ and 3×10¹⁹ atoms/cm³.

Method 1700 further includes a thermal treatment to activate the p-type dopant in the regrown III-nitride epitaxial layer (1714). In some embodiments, the thermal treatment may be performed in a furnace at temperatures from 600° C. to 800° C. In some embodiments, the thermal treatment may be performed in a rapid thermal annealer at temperatures from 700° C. to 850° C.

Method 700 further includes removing the patterned hard mask on the top surface of the second III-nitride layer (1716). In some embodiments where a composite hard mask layer is used, the top dielectric layer may be removed, leaving the metal layer.

Method 1700 further includes forming a source contact structure on the top surface of the second III-nitride layer (1718). In some embodiments, the metal hard mask layer is left in place, and the source contact structure is formed on top of the metal hard mask layer. In some embodiments, the source contact structure is formed using titanium and aluminum.

Method 1700 further includes forming a forming a gate contact structure on the conformal III-nitride layer (1720). The gate contact structure may include nickel, gold, palladium, platinum, molybdenum, and the like.

Method 1700 further includes forming a junction-terminated edge (“edge termination”) for the p-GaN layer at the lateral edges of the device active region (1722). In some cases, the p-GaN layer is connected to the gate, in others to the source. In some embodiments, this edge termination is formed using a tapered junction.

Method 1700 further includes forming a drain contact at the bottom side of the substrate by forming a metallic contact to the bottom side of substrate (1724).

It should be appreciated that the specific steps illustrated in FIG. 17 provide a particular method of fabricating a conformal epitaxial gate vertical FET according to an embodiment of the present invention. Other sequences of steps may also be performed according to alternative embodiments. For example, alternative embodiments of the present invention may perform the steps outlined above in a different order. Moreover, the individual steps illustrated in FIG. 17 may include multiple sub-steps that may be performed in various sequences as appropriate to the individual step. Furthermore, additional steps may be added or removed depending on the particular application. One of ordinary skill in the art would recognize many variations, modifications, and alternatives.

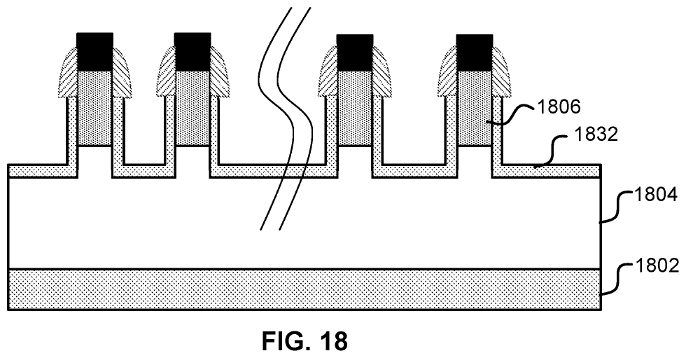

FIG. 18 is a cross-sectional diagram illustrating fabrication of another example of a conformal epitaxial gate vertical FET according to some embodiments of the present disclosure. These stages may be performed subsequent to the stages illustrated in FIGS. 1A-1E and FIGS. 7A-7E.

Referring to FIG. 18, a selective area regrowth can be used to form a regrown epitaxial layer 1832, e.g., a conformal, p-doped III-nitride regrown epitaxial layer, on the exposed surfaces of the first III-nitride layer 1804 and the second III-nitride layer 1806 in the fins. The first III-nitride layer 1804 can be coupled to a III-nitride substrate 1802. In an embodiment, the regrowth is performed using MOCVD. In an embodiment, the p-type dopant is Mg. In an embodiment, the regrowth is performed in an NH₃ ambient. In an embodiment, the regrowth is performed at pressures between 50 mbar and 600 mbar. In an embodiment, the regrowth is performed at temperatures between 850° C. and 950° C. In some embodiments, the regrown epitaxial layer 1832 has a thickness on the sidewalls of the trench of between 50-150 nm. In some embodiments, the p-type dopant concentration is between 5×10¹⁸ and 3×10¹⁹ atoms/cm³.

A thermal treatment can be performed to activate the p-type dopant in the regrown epitaxial layer 1832. In some embodiments, the thermal treatment may be performed in a furnace at temperatures from 600° C. to 800° C. In some embodiments, the thermal treatment may be performed in a rapid thermal annealer at temperatures from 700° C. to 850° C.

The stages illustrated in FIGS. 5F-5J may be performed subsequent to the stage illustrated in FIG. 18.

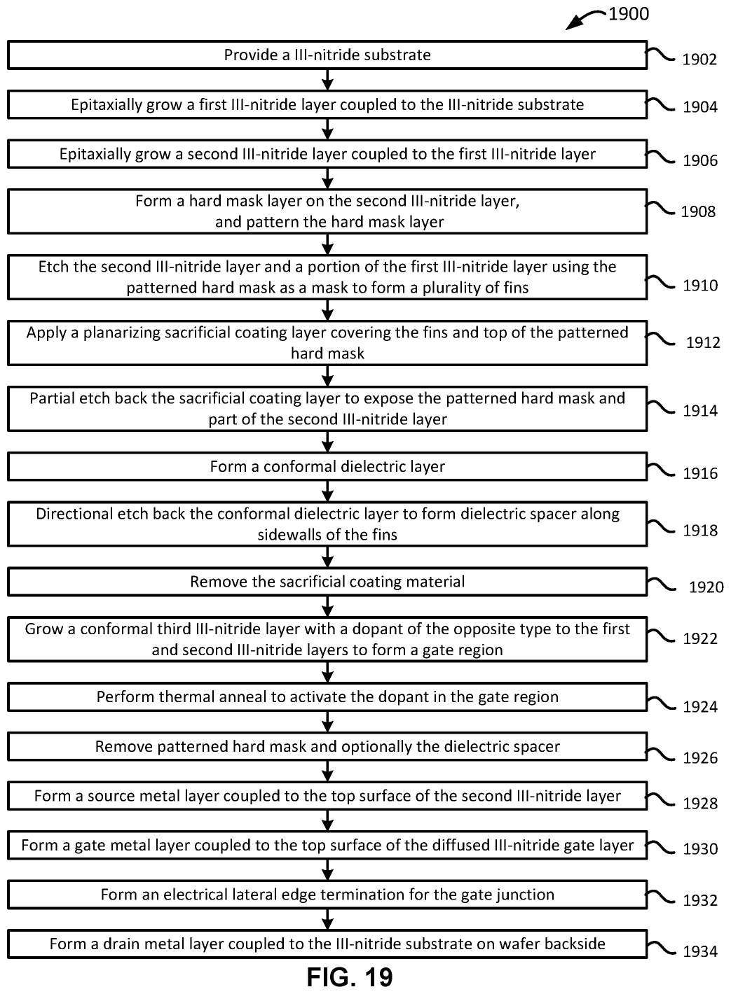

FIG. 19 is a flowchart illustrating another method for fabricating a conformal epitaxial gate vertical FET according to some embodiments of the present disclosure. A III-nitride substrate is provided (1902). In an embodiment, the III-nitride substrate is an N+ GaN substrate having a resistivity in a range of about 0.020 ohm-cm. In one embodiment, the resistivity of the N+ GaN substrate may be from about 0.001 ohm-cm to 0.018 ohm-cm, preferably less than 0.016 ohm-cm, and more preferably, less than 0.012 ohm-cm.

Method 1900 also includes forming a first III-nitride epitaxial layer, for example, a 5-12 μm thick first III-nitride epitaxial layer (e.g., an N− GaN epitaxial layer deposited on the III-nitride substrate (1904). The first III-nitride epitaxial layer is epitaxially grown on the III-nitride substrate at a temperature between 950 and 1100° C. and is characterized by a first dopant concentration, e.g., N-type doping with a dopant concentration of about 1×10¹⁶ atoms/cm³. In some embodiments, the first III-nitride epitaxial layer is a drift layer including a uniformly doped region (layer) on the III-nitride substrate and a graded doping region (layer) on the uniformly doped region. In an embodiment, the uniformly doped region has a thickness of about 10.5 μm, and the graded doping region has a thickness of about 0.3 μm. In an embodiment, the surface of substrate is miscut from the c-plane at an angle to facilitate high-quality epitaxial growth for high-voltage operation of the drift layer.

Method 1900 further includes forming a second III-nitride epitaxial layer on the first III-nitride epitaxial layer (1906). In an embodiment, the second III-nitride epitaxial layer is epitaxially grown on the first III-nitride epitaxial layer with a thickness of about 0.7-0.9 μm and is characterized by a second dopant concentration, e.g., N-type doping. The second dopant concentration is higher than the first dopant concentration in some embodiments. In an embodiment, the second dopant concentration is about 1.3×10¹⁷ atoms/cm³. In an embodiment, the second III-nitride epitaxial layer has a more highly doped surface layer, e.g., about 1-3×10¹⁸ atoms/cm³, with a thickness of 30-100 nm.

Method 1900 further includes forming and patterning a hard mask layer on the second III-nitride epitaxial layer (1908). In some embodiments, the hard mask layer may be a dielectric material such as silicon nitride, silicon dioxide, silicon oxynitride, silicon-aluminum nitride or the like. The dielectric material may be deposited by LPCVD, PECVD, ALD or the like. In some embodiments, the hard mask layer is a composite hard mask including a metal layer on the second III-nitride epitaxial layer and a dielectric hard mask layer on the metal layer. In some embodiments, the metal layer is a refractory metal, refractory metal alloy, or refractory metal nitride (e.g., TiN). The hard mask layer may be patterned using photolithography in combination with an RIE process. In some embodiments with a composite hard mask, the dielectric hard mask layer is first patterned, and then the patterned dielectric hard mask is used as a hard mask to pattern the metal layer.

Method 1900 further includes forming a recess region in the second III-nitride epitaxial layer using the patterned hard mask by an etch process, e.g., an RIE process (1910). In an embodiment, the etched recess extends into the first III-nitride epitaxial layer. In an embodiment, the etched recess extends partially (e.g., 0.1 μm) into the graded layer at the top of the first III-nitride epitaxial layer.

Method 1900 further includes applying a sacrificial coating layer to the surfaces of the fins and the patterned hard mask (1912) to create a substantially planar surface. In some embodiments, the sacrificial coating layer is a spin-on glass. In some embodiments, the sacrificial coating layer is silicon dioxide. In some embodiments, the sacrificial coating layer is deposited using PECVD. In some embodiments, the top surface of the sacrificial coating layer is 1-2 μm above the top surface of the patterned hard mask.

Method 1900 further includes etching back the sacrificial coating layer to expose the patterned hard mask and a portion of the sidewalls of the fins (1914). In some embodiments, the etch is performed using a fluorine-containing plasma.

Method 1900 further includes depositing a conformal dielectric layer on the exposed surfaces of the patterned hard mask, the fin sidewalls, and the sacrificial coating layer (1916). In some embodiments, the conformal dielectric layer is one of silicon nitride, silicon-aluminum nitride, or aluminum nitride. In some embodiments, the conformal dielectric layer is deposited by one of PECVD, LPCVD, or ALD.

Method 1900 further includes performing a directional (anisotropic) etch of the conformal dielectric layer (1918) to leave a “spacer” layer on the sidewalls of the patterned hard mask and a portion of the fin sidewalls. In some embodiments, the directional etch is performed using an RIE process.

Method 1900 further includes removal of the sacrificial coating layer (1920) to expose the remaining portions of the fin sidewalls and the trench bottom regions. In some embodiments, the sacrificial coating layer is removed using a wet etch.

Method 1900 further includes selective area regrowth of a conformal, p-doped III-nitride epitaxial layer on the exposed surfaces of the first and second semiconductor layers in the fins (1922). The p-doped III-nitride epitaxial layer is a dopant of the opposite type to the first and second III-nitride layers. In some embodiments, the regrowth is performed using MOCVD. In some embodiments, the p-type dopant is Mg. In some embodiments, the regrowth is performed in an NH₃ ambient. In some embodiments, the regrowth is performed at pressures between 50 mbar and 600 mbar. In some embodiments, the regrowth is performed at temperatures between 850° C. and 950° C. In some embodiments, the regrown epitaxial layer has a thickness on the sidewalls of the trench of between 50-150 nm. In some embodiments, the p-type dopant concentration is between 5×10¹⁸ and 3×10¹⁹ atoms/cm³.

Method 1900 further includes a thermal treatment to activate the p-type dopant in the regrown III-nitride epitaxial layer (1924). In some embodiments, the thermal treatment may be performed in a furnace at temperatures from 600° C. to 800° C. In some embodiments, the thermal treatment may be performed in a rapid thermal annealer at temperatures from 700° C. to 850° C.

Method 1900 further includes removing the patterned hard mask on the top surface of the second III-nitride layer (1926). Optionally, the spacer may also be removed. In some embodiments where a composite hard mask layer is used, the top dielectric layer may be removed, leaving the metal layer.

Method 1900 further includes forming a source contact structure on the top surface of the second III-nitride layer (1928). In some embodiments, the metal hard mask layer is left in place, and the source contact structure is formed on top of the metal hard mask layer. In some embodiments, the source contact structure is formed using titanium and aluminum.

Method 1900 further includes forming a forming a gate contact structure on that exposed surface portion of the regrown gate layer overlaying the top surface of the first III-nitride epitaxial layer (1930). The gate contact structure may include nickel, gold, palladium, platinum, molybdenum, and the like.

Method 1900 further includes forming a junction-terminated edge (“edge termination”) for the p-GaN layer at the lateral edges of the device active region (1932). In some cases, the p-GaN layer is connected to the gate, in others to the source. In some embodiments, this edge termination is formed using a tapered junction.

Method 1900 further includes forming a drain contact at the bottom side of the substrate by forming a metallic contact to the bottom side of substrate (1934).

It should be appreciated that the specific steps illustrated in FIG. 19 provide a particular method of fabricating a conformal epitaxial gate vertical FET according to an embodiment of the present invention. Other sequences of steps may also be performed according to alternative embodiments. For example, alternative embodiments of the present invention may perform the steps outlined above in a different order. Moreover, the individual steps illustrated in FIG. 19 may include multiple sub-steps that may be performed in various sequences as appropriate to the individual step. Furthermore, additional steps may be added or removed depending on the particular application. One of ordinary skill in the art would recognize many variations, modifications, and alternatives.

It should be understood that the drawings are not drawn to scale, and similar reference numbers are used for representing similar elements. As used herein, the terms “example embodiment,” “exemplary embodiment,” and “present embodiment” do not necessarily refer to a single embodiment, although it may, and various example embodiments may be readily combined and interchanged, without departing from the scope or spirit of the present invention. Furthermore, the terminology as used herein is for the purpose of describing example embodiments only and is not intended to be a limitation of the invention. In this respect, as used herein, the term “in” may include “in” and “on”, and the terms “a”, “an” and “the” may include singular and plural references. Furthermore, as used herein, the term “by” may also mean “from”, depending on the context. Furthermore, as used herein, the term “if” may also mean “when” or “upon”, depending on the context. Furthermore, as used herein, the words “and/or” may refer to and encompass any possible combinations of one or more of the associated listed items.

It will be understood that, although the terms “first,” “second,” “third,” etc. may be used herein to describe various elements, components, regions, layers, and/or sections, these elements, components, regions, layers, and/or sections should not be limited by these terms. These terms are only used to distinguish one element, component, region, layer, or section from another region, layer or section. Thus, a first element, component, region, layer, or section discussed below could be termed a second element, component, region, layer, or section without departing from the teachings of the present invention.

The term “horizontal” as used in this application is defined as a plane parallel to the conventional plane or surface of a wafer or substrate, regardless of the orientation of the wafer or substrate. The term “vertical” refers to a direction perpendicular to the horizontal as defined above. Prepositions, such as “on”, “side” (as in “sidewall”), “below”, “above”, “higher”, “lower”, “over”, and “under” are defined with respect to the conventional plane or surface being on the top surface of the wafer or substrate, regardless of the orientation of the wafer or substrate. It will be understood that these terms are intended to encompass different orientations of the device in addition to the orientation depicted in the figures.

Although embodiments of the present disclosure have been described in detail, it should be understood that various modifications, substitutions and variations can be made hereto without departing from the scope of the invention as defined by the appended claims.

What is claimed is:

1. A vertical FET device comprising:
a semiconductor structure comprising a semiconductor substrate, a first semiconductor layer coupled to the semiconductor substrate, and a second semiconductor layer coupled to the first semiconductor layer;
a plurality of fins, wherein adjacent fins of the plurality of fins are separated by a trench extending into the second semiconductor layer and wherein each of the plurality of fins includes a channel region disposed in the second semiconductor layer;
a gate region extending into a sidewall portion of the channel region of each of the plurality of fins;
a source metal structure coupled to the second semiconductor layer;
a gate metal structure coupled to the gate region; and
a drain contact coupled to the semiconductor substrate.

2. The vertical FET device of claim 1 further comprising a drift region disposed in the first semiconductor layer.

3. The vertical FET device of claim 1 wherein the gate region extends along a horizontal surface of the first semiconductor layer.

4. The vertical FET device of claim 1 wherein the gate region extends along vertical surfaces of the plurality of fins.

5. The vertical FET device of claim 1 wherein sidewalls of the plurality of fins include an undiffused section.

6. The vertical FET device of claim 1 wherein the gate region comprises a p-GaN gate layer.

7. The vertical FET device of claim 1 wherein a dopant concentration between the gate region and the first semiconductor layer is 1-3×10¹⁹ atoms/cm³.

8. The vertical FET device of claim 1 wherein the gate region comprises a junction depth between 25 and 50 nm.

9. A method for manufacturing a vertical FET device, the method comprising:
providing a semiconductor substrate;
epitaxially growing a first semiconductor layer coupled to the semiconductor substrate;
epitaxially growing a second semiconductor layer coupled to the first semiconductor layer;
forming a patterned hard mask coupled to the second semiconductor layer;
etching the second semiconductor layer and a portion of the first semiconductor layer to form a plurality of fins;
applying a diffusion dopant layer;
applying a sacrificial planarization layer on the diffusion dopant layer;
selectively etching the sacrificial planarization layer to expose the diffusion dopant layer;
removing an exposed portion of the diffusion dopant layer and the sacrificial planarization layer;
performing a thermal treatment to diffuse the diffusion dopant layer into the first semiconductor layer and form a diffused gate layer;
removing the diffusion dopant layer and the patterned hard mask;
forming a source metal structure coupled to a top surface of the second semiconductor layer;
forming a gate metal structure coupled to the diffused gate layer; and
forming a drain contact coupled to a bottom surface of the semiconductor substrate.

10. The method of claim 9 further comprising forming an edge termination for the diffused gate layer overlaying a top surface of the first semiconductor layer.

11. The method of claim 9 wherein the diffusion dopant layer comprises a metal layer formed with a p-type dopant.

12. The method of claim 9 wherein selectively etching the sacrificial planarization layer comprises a reactive-ion etch.

13. The method of claim 9 wherein a dopant metallurgical concentration between the diffusion dopant layer and the first semiconductor layer is 1-3×10¹⁹ atoms/cm³.

14. The method of claim 9 wherein the diffused gate layer extends along a portion of sidewalls of the second semiconductor layer.

15. The method of claim 9 wherein the drain contact comprises titanium, aluminum, or a combination thereof.

16. A method for manufacturing a conformal-gate vertical FET device, the method comprising:
providing a semiconductor structure including a substrate, a first semiconductor layer, and a second semiconductor layer;
forming a plurality of fins having sidewall surfaces in a portion of the first semiconductor layer and the second semiconductor layer, wherein the plurality of fins are separated by trenches;
growing a third semiconductor layer coupled to the sidewall surfaces of the plurality of fins, wherein the third semiconductor layer includes a dopant and comprises a recessed gate region; and
forming a source metal, a gate metal, and a drain contact.

17. The method of claim 16 further comprising performing a thermal treatment to activate the dopant in the recessed gate region.

18. The method of claim 16 wherein the third semiconductor layer extends along a portion of the sidewall surfaces of the plurality of fins.

19. The method of claim 16 further comprising forming an edge termination for the recessed gate region overlaying a top surface of the first semiconductor layer.

20. The method of claim 16 wherein the third semiconductor layer comprises a conformal layer.
